(19) United States
(12) Patent Application Publication
(10) Pub. No.: US 2026/0017552 A1
(43) Pub. Date: Jan. 15, 2026

(54) QUBIT ADJUSTMENT

(71) Applicant: Oxford Quantum Circuits Limited, Reading (GB)

(72) Inventors: Yashwanth Balaji, Reading (GB); Narendra Acharya, Reading (GB); Kowsar Shahbazi, Reading (GB); Oscar Kennedy, Reading (GB); Connor Shelly, Reading (GB)

(21) Appl. No.: 19/334,596

(22) Filed: Sep. 19, 2025

Related U.S. Application Data
(63) Continuation of application No. PCT/GB2024/050741, filed on Mar. 19, 2024.

(30) Foreign Application Priority Data
Mar. 21, 2023 (GB) 2304133.8
Aug. 2, 2023 (GB) 2311851.6
Dec. 6, 2023 (GB) 2318634.9

(51) Int. Cl. G06N 10/40

(52) U.S. Cl. CPC G06N 10/40

(57) ABSTRACT

A method of adjusting the frequency of a qubit comprising a Josephson junction. The method comprises directing an electron beam to heat the Josephson junction. The method further comprises cooling the Josephson junction following the heating of the Josephson junction by the electron beam. The heating and cooling of the Josephson junction serves to alter a resistance of the Josephson junction, and wherein the alteration of the resistance of the Josephson junction changes the frequency of the qubit.

### CROSS REFERENCE TO RELATED APPLICATIONS

This application is a continuation of International Patent Application No. PCT/GB2024/050741 filed Mar. 19, 2024 and entitled “QUBIT ADJUSTMENT,” which claims priority to United Kingdom Patent Application No. 2304133.8 filed Mar. 21, 2023, United Kingdom Patent Application No. 2311851.6 filed Aug. 2, 2023 and United Kingdom Patent Application No. 2318634.9 filed Dec. 6, 2023, all of which are incorporated herein by reference in their entirety.

The present disclosure relates to quantum computing. In particular, the present disclosure relates to methods and apparatus for adjusting the frequency of a qubit which may form part of a quantum computer.

### BACKGROUND

A quantum computer is a device which utilises quantum mechanical effects to process quantum information. The basic unit of quantum information used in quantum computing is a qubit. A qubit has two basis states and is analogous to a bit used in classical computing. However, unlike a classic bit, which can only exist in one of its two states at any given time, a qubit can exist in a superposition of both of its states simultaneously. The overall superposition of states in a quantum computer scales as 2ⁿ where n is the number of qubits placed in a superposition of states. A quantum computer can use such a superposition of states, along with other quantum mechanical effects, such as quantum entanglement, to solve various computational problems. In particular, quantum computing has the potential to solve a range of computational problems which remain out of reach of even the world's largest classical supercomputers.

A practical quantum computer is configured to establish, maintain and manipulate a plurality of physical qubits. Physical qubits may be realised by maintaining and manipulating a two-state quantum mechanical physical system. One form of realisation of a physical qubit is a so-called superconducting qubit. Superconducting qubits comprise superconducting electronic circuits, which typically include a Josephson junction. A Josephson junction is a nonlinear inductive element, which in practice serves to create a distinct difference between energy levels in a superconducting qubit. This distinct energy level difference allows the qubit energy levels to be addressed (typically by exposure to microwave radiation) and a superconducting qubit manipulated to cause transitions between its energy levels.

A superconducting qubit including a Josephson junction has a resonance frequency associated with it. The resonance frequency of the superconducting qubit determines the frequency at which the qubit is driven to realise transitions between its energy levels. In their simplest form, the resonance frequency of a superconducting qubit is fixed during fabrication of the superconducting qubit and is a property of variables such as the critical current of the Josephson junction and the capacitance of the qubit.

Fabrication of Josephson junctions can be subject to variance. For example, a Josephson junction may be fabricated with a given set of target or design parameters. However, in practice a given fabricated Josephson junction's parameters (such as physical dimensions, a critical current, resistance and/or qubit frequency) may vary from its target values for which the fabrication process was designed. For example, if a plurality of superconducting qubits are fabricated using a near-identical fabrication process (for example, with the same target or design parameters) then variance in the fabrication process may result in dispersion in the frequencies of the qubits.

Superconducting qubits have been proposed whose frequencies are dynamically tuneable during operation, typically subject to some form of control signal. However, such dynamically tuneable qubits require extra components and electromagnetic signals to enter the qubits, which may increase complexity and noise. It may therefore be desirable to more accurately set the frequency of a qubit prior to operation so as to avoid the need for dynamic frequency tuneability during operation of the qubit. Additionally or alternatively, even where frequency tuneable qubits are used, there may still be advantages associated with being able to more accurately control the resonance frequency of a superconducting qubit prior to operation (and prior to any tuning of the frequency which may occur during operation).

Methods have been proposed to alter the frequency of a superconducting qubit after fabrication of a Josephson junction. For example, methods have been proposed to anneal a Josephson junction using a laser beam. Further proposals have been made to anneal a Josephson junction through exposure to radio frequency radiation.

It is in this context that the subject matter contained in the present application has been devised.

### SUMMARY

It has been realised that the frequency of a qubit can be adjusted prior to operation by directing an electron beam to heat a Josephson junction which forms part of the qubit. Such heating of a Josephson junction using an electron beam has been found to provide a highly controllable technique for altering the resistance of the Josephson junction, which in turn allows for adjustment of a resonance frequency of the qubit in which the Josephson junction is incorporated. In particular, it has been found that an electron beam can provide localised heating of a Josephson junction allowing for independently controllable adjustment of individual qubits and without significant influence on the frequency of neighbouring qubits. It has further been found that through suitable control of electron beam currents and total doses used to heat a Josephson junction, the resistance of the Josephson junction can be selectively controlled to undergo either an increase or a decrease. Correspondingly the frequency of a qubit in which the Josephson junction is incorporated can be selectively adjusted to either decrease or increase as required.

According to a first aspect of the present disclosure there is provided, a method of adjusting the frequency of a qubit comprising a Josephson junction. The method comprises directing an electron beam to heat the Josephson junction, and cooling the Josephson junction following the heating of the Josephson junction by the electron beam. The heating and cooling of the Josephson junction serves to alter a resistance of the Josephson junction. The alteration of the resistance of the Josephson junction changes the frequency of the qubit.

The heating and cooling of the Josephson junction may serve to anneal the Josephson junction and may be referred to as electron beam annealing of the Josephson junction. The heating and cooling of the Josephson junction may serve to change a material property of at least one component of the Josephson junction.

The inventors have demonstrated that electron beam annealing of Josephson junctions, as described herein, can be used to adjust the frequencies of qubits in a quantum information processor. In particular, the inventors have demonstrated that the electron beam annealing can be used to adjust frequencies of qubits in a quantum information processor in order to reduce a spread of frequencies of the qubits. It has further been demonstrated that after applying an electron beam annealing process to qubits (in order to adjust their frequencies), a coherence time of the qubits is not adversely affected and the qubits remain as high coherence qubits (having a relatively long coherence time) after the electron beam annealing process is applied.

The cooling of the Josephson junction following the heating of the Josephson junction may comprise allowing the Josephson junction to cool. For example, no electron beam may be directed to heat the Josephson junction for a cooling period of time, thereby allowing the Josephson junction to cool. The cooling of the Josephson junction may not include any active cooling of the Josephson junction. However, in other examples active cooling may be applied to the Josephson junction in order to cool the Josephson junction.

The Josephson junction may comprise two superconductors separated by a barrier. The superconductors may, for example, comprise aluminium. The barrier may comprise a non-superconducting material and/or an electrically insulating material. The barrier may comprise an aluminium oxide. The barrier may be sufficiently thin to allow for quantum tunnelling across the barrier and between the two superconductors.

In some examples, the qubit may comprise a single Josephson junction. In other examples, the qubit may comprise a plurality of Josephson junctions. In examples, in which the qubit comprises a plurality of Josephson junctions, the method may comprise directing the electron beam to heat one of the plurality of Josephson junctions (and cooling the Josephson junction). Alternatively the method may comprise directing an electron beam to heat more than one Josephson junction (either at the same or different times) and cooling the more than one Josephson junction. The more than one Josephson junction may comprise all of the plurality of Josephson junctions included in the qubit or may comprise less than all of the plurality of Josephson junctions including in the qubit.

Directing the electron beam to heat the Josephson junction may comprise directing the electron beam to be incident on the Josephson junction.

For example, the electron beam may be directed to be directly incident on at least a portion of the Josephson junction itself thereby inducing at least some direct heating of at least one component of the Josephson junction.

In some examples, the electron beam may be directed so as not to be directly incident on the Josephson junction.

Directing the electron beam to heat the Josephson junction may comprise directing the electron to beam incident on a component which is thermally coupled to the Josephson junction, thereby causing heating of the component and heating of the Josephson junction through heat conduction from the heated component.

Directing the electron beam to be incident on a component which is thermally coupled to the Josephson junction causes indirect heating of the Josephson junction. That is, the component is directly heated by the electron beam, which in turn serves to indirectly heat the Josephson junction through thermal conduction from the heated component. Indirect heating of a Josephson junction may reduce a risk of causing damage to the Josephson junction, since it is possible that direct heating may, under at least some conditions, cause damage to a Josephson junction which may adversely affect its performance.

The component may be in proximity to at least a portion of the Josephson junction.

The component may comprise a portion of a substrate supporting the Josephson junction. The Josephson junction may, for example, be supported on a substrate comprising silicon or sapphire. The component may comprise a portion of the substrate which is in proximity to the Josephson junction. That is, an electron beam may be directed to be incident on the substrate at a position proximate to the Josephson junction.

The Josephson junction may be connected between two superconducting electrodes.

The superconducting electrodes may be arranged to be coaxial with each other. The superconducting electrodes may be coplanar with each other. For example, the superconducting electrodes may be situated on the same surface (such as a surface of a substrate).

The directing an electron beam to heat the Josephson junction may comprise directing the electron beam with a first current below a threshold current so as to increase the resistance of the Josephson junction and decrease the frequency of the qubit.

The directing an electron beam to heat the Josephson junction may comprise directing the electron beam with a first current greater than a threshold current so as to decrease the resistance of the Josephson junction and increase the frequency of the qubit.

The directing an electron beam to heat the Josephson junction may comprise directing the electron beam to heat the Josephson junction for a single continuous exposure time period.

The directing an electron beam to heat the Josephson junction may comprise directing a plurality of pulses of the electron beam to heat the Josephson junction.

The plurality of pulses of the electron beam may be directed to heat the Josephson junction for a plurality of successive exposure time periods. The plurality of successive exposure time periods may be separated by time periods in which no electron beam is directed to heat the Josephson junction. Alternatively, at least some of the plurality of pulses of the electron beam may be directed to heat the Josephson junction at the same time. For example, a plurality of electron sources may be used to direct a plurality of electron beams to heat the Josephson junction at the same time.

At least some of the plurality of pulses of an electron beam may be directed to be incident at a plurality of different positions.

The directing an electron beam to heat the Josephson junction may comprise directing the electron beam to be incident on a plurality of different positions. For example, an electron beam may be directed to be incident on a plurality of different portions of the Josephson junction and/or a component (e.g., a substrate supporting the Josephson junction) which is thermally coupled to the Josephson junction. The electron beam may be directed to be incident on a plurality of different positions at successive times. For example, the electron beam may be directed to be incident on a first position at a first time followed by a second position at a second time. Additionally or alternatively, electron beams may be directed to be incident on a plurality of different positions at the same time. For example, a plurality of electron sources may be used to direct a plurality of electron beams to be incident on a plurality of different positions at the same time to heat the Josephson junction.

The different positions at which an electron beam may be directed to be incident on may be controlled to control the heating of the Josephson junction. An electron beam typically has a beam diameter which is smaller than the dimensions of a Josephson junction (e.g., the beam diameter may be several times, and even an order of magnitude or more, smaller than a dimension of the Josephson junction). The relatively small beam diameter of the electron beam (relative to the Josephson junction) allows the location at which the electron beam is positioned, relative to the Josephson junction, to be precisely controlled so as to carefully control heating of the Josephson junction.

The different positions at which an electron beam may be directed to be incident on, may be arranged to form an exposure pattern. The exposure pattern may be controlled to control a degree of heating of the Josephson junctions (and the resistance change which is induced by the heating). An exposure pattern may comprise a plurality of different exposure spots on which an electron beam may be directed to be incident. The plurality of different exposure spots may comprise at least some exposure spots on at least a portion of the Josephson junction. Additionally or alternatively, the plurality of different exposure spots may comprise at least some exposure spots which are not located on the Josephson junction. For example, at least some of the exposure spots may be located on a component (e.g., a supporting substrate) which is thermally coupled to the Josephson junction.

In some examples, an exposure pattern may comprise a plurality of exposure spots arranged in a substantially uniform grid pattern. The grid pattern may, for example, be substantially centered on the Josephson junction.

The plurality of different positions may be arranged to form an exposure pattern which encloses the Josephson junction.

The exposure pattern may, for example, comprise a plurality of exposure spots arranged to form one or more loops around the Josephson junction. The arrangement of exposure spots may include gaps in between adjacent exposure spots such that the exposure spots do not form an entirely closed loop which fully enclose the Josephson junction. However, such arrangements still form a pattern which is arranged to generally enclose the Josephson junction, even if there are gaps between adjacent exposure spots.

The directing an electron beam to heat the Josephson junction may comprise directing an electron beam having a beam diameter of less than 200 nm to heat the Josephson junction.

The directing an electron beam to heat the Josephson junction may comprise directing an electron beam having a beam diameter of less than 100 nm to heat the Josephson junction.

The directing an electron beam to heat the Josephson junction may comprise directing an electron beam having a beam diameter of less than 50 nm to heat the Josephson junction.

The use of an electron beam may allow relatively small beam diameters to be used which may provide highly localised and/or highly controllable heating of a Josephson junction. Localised heating of a Josephson junction may allow for a single Josephson junction to be independently and selectively heated without significantly heating any nearby Josephson junctions (and altering their resistance and equivalently qubit frequency). In general an electron beam may be used which has a beam diameter which is less than a diameter of a laser beam. An electron beam may therefore advantageously be used to provide more localised and/or more controllable heating to a Josephson junction than a laser beam.

The directing an electron beam to heat the Josephson junction may comprise directing an electron beam having a current of greater than 0.1 nA to heat the Josephson junction.

The directing an electron beam to heat the Josephson junction may comprise directing an electron beam having a current greater than 1 nA. The directing an electron beam to heat the Josephson junction may comprise directing an electron beam having a current which is less than 1000 nA. For example, the electron beam may have a current which is less than approximately 500 nA and may be generated with a current which is less than approximately 200 nA.

The directing an electron beam to heat the Josephson junction may comprise using an electron beam lithography apparatus to direct the electron beam to heat the Josephson junction.

An electron beam lithography apparatus may comprise an electron source configured to generate an electron beam and direct the electron beam to heat a Josephson junction. The electron beam lithography apparatus may comprise a stage for supporting a substrate on which the Josephson junction is situated and for aligning the Josephson junction relative to the electron beam. The electron beam lithography apparatus may further be configured to generate vacuum pressure conditions under which the electron beam is directed to heat the Josephson junction.

In other examples, other apparatus and/or electron sources may be used to heat a Josephson junction. For example, a scanning electron microscope may be used to direct an electron beam to heat a Josephson junction.

According to a second aspect of the present disclosure there is provided a method of adjusting qubit frequencies of a quantum information processor comprising a plurality of qubits, wherein each qubit comprises a Josephson junction. The method comprises: determining a frequency of each of the plurality of qubits, identifying, based on the determined frequencies of the plurality of qubits, at least one of the qubits for frequency adjustment, and adjusting a frequency of the at least one qubit identified for frequency adjustment. The adjusting a frequency of the at least one qubit identified for frequency adjustment may comprise: directing an electron beam to heat a Josephson junction included in the at least one qubit identified for frequency adjustment; and cooling the Josephson junction following the heating of the Josephson junction by the electron beam. The heating and cooling of the Josephson junction serves to alter a resistance of the Josephson junction, and the alteration of the resistance of the Josephson junction changes the frequency of the at least one identified qubit.

Determining a frequency of each of the plurality of qubits may comprise directly determining the frequencies themselves. Alternatively, determining a frequency of each of the plurality of qubits may comprise determining a variable which is indicative of the frequency (such as a resistance of a Josephson junction).

Determining a frequency of each of the plurality of qubits may comprise measuring a resistance of a Josephson junctions included in each of the plurality of qubits.

Identifying at least one of the plurality of qubits for frequency adjustment may comprise identifying at least one of the plurality of qubits having a frequency which can be adjusted to reduce a dispersion of the frequencies of the plurality of qubits.

For example, identifying at least one of the plurality of qubits for frequency adjustment may comprise identifying at least one of the qubits having a frequency which varies from a mean frequency of all of the qubits. Identifying at least one of the plurality of qubits for frequency adjustment may comprise identifying at least one of the plurality of qubits having a frequency which is less than the mean frequency. Identifying at least one of the plurality of qubits for frequency adjustment may comprise identifying at least one of the plurality of qubits having a frequency which is greater than the mean frequency.

Adjusting the frequency of the at least one qubit identified for frequency adjustment may comprise adjusting the frequency of the at least one identified qubit so as to reduce a dispersion of the frequencies of the plurality of qubits.

The dispersion of the frequencies of the plurality of qubits may comprise a measure such as a variance and/or standard deviation of the frequencies of the plurality of qubits.

Adjusting the frequency of the at least one qubit identified for frequency adjustment may comprise adjusting the frequency of the at least one identified qubit so as to adjust the frequencies of the at least one identified qubit so as to move them closer to a mean frequency of all of the qubits. Such an adjustment may serve to reduce the dispersion of the frequencies of the plurality of qubits.

The adjusting the frequency of the at least one qubit identified for frequency adjustment may comprise increasing the resistance of a Josephson junction of at least a first of the at least one qubit identified for frequency adjustment so as to decrease the frequency of the at least a first of the at least one qubit identified for frequency adjustment.

Increasing the resistance of the Josephson junction may comprise directing an electron beam having a current less than a threshold current to heat the Josephson junction.

The adjusting the frequency of the at least one qubit identified for frequency adjustment may comprise decreasing the resistance of a Josephson junction of at least a second of the at least one qubit identified for frequency adjustment so as to increase the frequency of the at least a second of the at least one qubit identified for frequency adjustment. Decreasing the resistance of the Josephson junction may comprise directing an electron beam having a current greater than a threshold current to heat the Josephson junction.

The adjusting a frequency of the at least one qubit identified for frequency adjustment, may further comprise: determining a property of the electron beam to be directed to heat a Josephson junction in dependence on a determined frequency of a qubit in which the Josephson junction is included, and directing the electron beam to heat the Josephson junction with the determined property of the electron beam.

The property of the electron beam to be directed to heat the Josephson junction may comprise one or more of an electron beam current, a charge dose to be delivered by the electron beam, a time period during which the electron beam is directed to heat the Josephson junction, a number of positions at which the electron beam is directed to heat the Josephson junction and/or a position at which the electron beam is directed to heat the Josephson junction (e.g., a proximity of the electron beam to the Josephson junction).

According to a third aspect of the present disclosure there is provided a quantum information processor comprising at least one qubit comprising a Josephson junction, wherein the frequency of the at least one qubit has been adjusted using a method according to the first aspect.

According to a fourth aspect of the present disclosure there is provided a quantum information processor comprising a plurality of qubits each comprising a Josephson junction, wherein the frequency of at least one of the plurality of qubits has been adjusted using a method according to the third aspect.

Within the scope of this application it is expressly intended that the various aspects, embodiments, examples and alternatives set out in the preceding paragraphs, in the claims and/or in the following description and drawings, and in particular the individual features thereof, may be taken independently or in any combination. That is, all examples and/or features of any example can be combined in any way and/or combination, unless such features are incompatible. The applicant reserves the right to change any originally filed claim or file any new claim accordingly, including the right to amend any originally filed claim to depend from and/or incorporate any feature of any other claim although not originally claimed in that manner.

### BRIEF DESCRIPTION OF THE DRAWINGS

One or more embodiments of the invention are shown schematically, by way of example, only in the accompanying drawings in which:

FIG. 1 is a schematic illustration of an example of an electron beam being directed to heat a superconducting qubit;

FIG. 2 is a schematic illustration of a further example of an electron beam being directed to heat a superconducting qubit;

FIG. 3 is a schematic illustration of an example of an electron beam being directed to heat a Josephson junction which may form part of a superconducting qubit;

FIG. 4 is a schematic illustration of a quantum information processor comprising a plurality of superconducting qubits;

FIG. 5 is a flowchart of an example method of adjusting the frequency of a qubit;

FIG. 6 is a schematic illustration of a plurality of different exposure patterns to which a Josephson junction may be subjected during and electron beam annealing process;

FIG. 7 is a schematic illustration of exposure patterns at three different distances from a Josephson junction during electron beam annealing processes;

FIG. 8A is a histogram illustrating the resistances of a plurality of Josephson junctions before and after being subjected to an example electron beam annealing process;

FIG. 8B is a scatter graph illustrating the resistances of a plurality of Josephson junctions before and after being subjected to the example electron beam annealing process shown in FIG. 8A;

FIG. 9 is a flowchart of an example method of adjusting qubit frequencies of a quantum information processor comprising a plurality of qubits;

FIG. 10A is a histogram illustrating resistances of a first group of Josephson junctions which are included in qubits of a first quantum information processor;

FIG. 10B are histograms illustrating resistances of the first group of Josephson junctions before and after being subjected to a further example electron beam annealing process;

FIG. 10C is a histogram illustrating the resistances of the first group of Josephson junctions before and after being subjected to the further example electron beam annealing process;

FIG. 10D is a scatter graph illustrating the resistances of the first group of Josephson junctions before and after being subjected to the further example electron beam annealing process;

FIG. 11A is a histogram illustrating resistances of a second group of Josephson junctions which are included in qubits of a second quantum information processor;

FIG. 11B are histograms illustrating resistances of the second group of Josephson junctions before and after being subjected to a still further example electron beam annealing process;

FIG. 11C is a histogram illustrating the resistances of the second group of Josephson junctions before and after being subjected to the still further example electron beam annealing process;

FIG. 11D is a scatter graph illustrating the resistances of the second group of Josephson junctions before and after being subjected to the still further example electron beam annealing process; and

FIG. 12A is a schematic illustration of an exposure pattern located at a plurality of different positions relative to a Josephson junction;

FIG. 12B is a graph of changes in resistance to Josephson junctions which result from directing exposure patterns to be incident at different separations from the Josephson junctions;

FIG. 13A is a schematic illustration of different exposure patterns which were used to generate results which are shown in FIG. 13B;

FIG. 13B is a graph of changes in resistance to Josephson junctions which resulted from subjecting Josephson junctions to different electron beam annealing processes using different exposure patterns;

FIG. 14 is a schematic illustration of an electronic device which may be used to implement one or more method steps disclosed herein.

### DETAILED DESCRIPTION

Before particular examples of the present invention are described, it is to be understood that the present disclosure is not limited to the particular examples described herein. It is also to be understood that the terminology used herein is used for describing particular examples only and is not intended to limit the scope of the claims.

In describing and claiming the apparatus and methods of the present invention, the following terminology will be used: the singular forms “a”, “an”, and “the” include plural forms unless the context clearly dictates otherwise. Thus, for example, reference to “a Josephson junction” or “a qubit” includes reference to one or more of such elements.

References are made herein to a qubit and/or to a plurality of qubits. Unless indicated otherwise, such references are intended to refer to physical qubits. That is, references to qubits are intended to refer to physical systems which when suitably operated and controlled give rise to physical qubits. Such systems may only function as physical qubits under certain operating conditions. For example, a superconducting qubit only exhibits the behaviour of a qubit when cooled to a sufficiently low temperature such that components of the qubit exhibit superconductivity. References herein to a qubit (or physical qubit) are intended to encompass arrangements of components which are capable of functioning as qubits (for example, when cooled to suitably low temperatures) even under conditions in which they do not necessarily function as qubits. For example, an arrangement of components (such as a parallel connection of a Josephson junction and a capacitor) which function as a qubit when cooled to suitably low temperatures, may still be referred to as a qubit when not cooled to such temperatures (for example, when at room temperature or some other temperature at which they do not exhibit the behaviour of a qubit). References herein to a qubit are therefore intended to encompass arrangements of components which are capable of behaving as qubits under suitable operating conditions even when they are not subject to those operating conditions.

Similarly, references are also made herein to superconducting materials, superconducting components (such as electrodes) and/or superconducting qubits. It will be appreciated that such materials, components and/or qubits only behave as superconductors when cooled to suitably low temperatures. However, references herein to superconducting materials, superconducting components (such as electrodes) and/or superconducting qubits are intended to encompass such materials, components and/or qubits which are capable of exhibiting superconductivity even when they are under conditions in which they do not exhibit superconductivity. For example, materials, components and/or qubits which behave as superconductors when cooled to suitably low temperatures may still be referred to as superconducting materials, components and/or qubits when not cooled to such temperatures (for example, when at room temperature or some other temperature at which they do not behave as superconductors). References herein to superconducting materials, components (such as electrodes) and/or qubits are therefore intended to encompass materials, components and/or qubits which are capable of behaving as superconductors under suitable operating conditions even when they are not subject to those operating conditions.

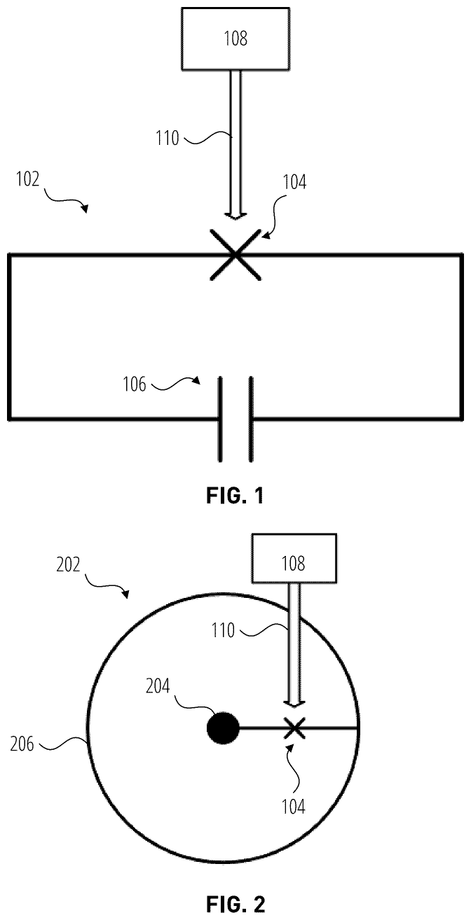

FIG. 1 is a schematic illustration of an example of a superconducting qubit 102. The superconducting qubit 102 comprises a Josephson junction 104 connected in parallel with a capacitor 106. Such an arrangement may be referred to as a charge qubit and may be referred to more specifically as a transmon qubit. The components and connections which make up the qubit 102 may be constructed from superconducting materials (for example, aluminium) such that they exhibit superconductivity under suitable operating conditions (for example, when cooled to suitable low temperatures).

FIG. 2 is a schematic illustration of an example arrangement of a superconducting qubit 202. The superconducting qubit 202 depicted in FIG. 2 comprises a Josephson junction 104 connected between a first superconducting electrode 204 and a second superconducting electrode 206. The first superconducting electrode 204 and the second superconducting electrode 206 are arranged such that they are coaxial with each other. The first superconducting electrode 204 and the second superconducting electrode 206 may further be arranged to be coplanar with each other. For example, the first superconducting electrode 204 and the second superconducting electrode 206 may be positioned on the same surface (such as a surface of a substrate). The components and connections which make up the qubit 202 may be constructed from superconducting materials (for example, aluminium) such that they exhibit superconductivity under suitable operating conditions (for example, when cooled to suitably low temperatures).

A qubit 202 having the arrangement depicted in FIG. 2 may also be considered to be a form of charge qubit and/or transmon, the capacitance of the transmon qubit being provided by the capacitance between the first superconducting electrode 204 and the second superconducting electrode 206. The coaxial arrangement of electrodes 204, 206 as shown in FIG. 2 has been shown to exhibit a number of advantageous effects for operation as a superconducting qubit. For example, the coaxial arrangement of electrodes 204, 206 as shown in FIG. 2 provide improved isolation from the electromagnetic environment, thereby reducing crosstalk and improving coherence times. Qubits of the type depicted in FIG. 2 are described in more detail in patent publication WO2017/021714 which is incorporated herein by reference in its entirety.

Whilst not shown in FIG. 1 or FIG. 2 when a qubit 102, 202 is implemented in a quantum computer it may be coupled to a control line and/or a readout line. A control line may be coupled to the qubit 102, 202 to control the state of the qubit 102, 202. For example, a control line may be used to expose a qubit 102, 202 to suitable pulses of microwave radiation, which may, for example, cause the qubit 102, 202 to transition between its energy levels. A readout line may be coupled to the qubit 102, 202 to measure the state of the qubit 102, 202. For example, a microwave signal may be applied to a readout line and the amplitude and/or phase of the applied microwave signal may be measured in order to determine a resonant frequency of the readout line. The resonant frequency of the readout line may depend on the state of the qubit 102, 202 to which the readout line is coupled, thereby allowing for measurement of the state of the qubit 102, 202.

For qubits 202 having an arrangement of the form shown in FIG. 2, a control line and/or readout line may be provided which is coaxial with the first superconducting electrode 204 and the second superconducting electrode 206. Furthermore, a control line and/or a readout line may be provided which are out of plane with respect to the first superconducting electrode 204 and the second superconducting electrode 206. Further details of arrangements of a control line and/or a readout line which may be coupled to a qubit 202 of the form shown in FIG. 2 is provided in patent publication WO2017/021714.

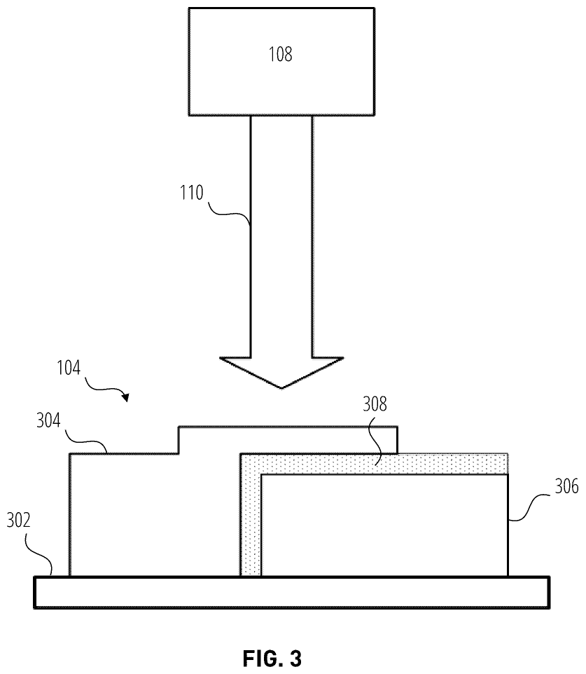

FIG. 3 is a schematic illustration of an example of a Josephson junction 104, which may form part of any qubit described herein. For example, a Josephson junction 104 of the type illustrated in FIG. 3 may form a Josephson junction 104 included in a qubit 102 of the type shown in FIG. 1 and/or a Josephson junction 104 included in a qubit 202 of the type shown in FIG. 2.

The Josephson junction 104 depicted in FIG. 3 comprises a first superconductor 304 and a second superconductor 306. The first superconductor 304 and the second superconductor 306 may be formed of a suitable superconducting material such as aluminium. The first superconductor 304 and the second superconductor 306 are separated from each other by a barrier 308. The barrier 308 may be formed of an electrically insulating material or an otherwise non-superconducting material. In at least some examples the barrier 308 is formed of an aluminium-oxide. The barrier 308 may be sufficiently thin to provide a weak link between the first superconductor 304 and the second superconductor 306 and to allow for quantum tunnelling between the first superconductor 304 and the second superconductor 306. In examples in which the barrier 308 is formed of an aluminium oxide, the barrier 308 may have a thickness in the range of approximately 0.1 and 10 nanometres (nm), which may be sufficiently thin to allow quantum tunnelling across the aluminium oxide barrier 308.

As shown in FIG. 3 the Josephson junction 104 may be fabricated on or otherwise supported by a substrate 302. The substrate 302 may be formed of a low loss dielectric material such as silicon or sapphire.

Whilst not shown in FIG. 3, the first superconductor 304 and the second superconductor 306 may be electrically connected to other components of a qubit 102, 202. For example, the first superconductor 304 and the second superconductor 306 may each be respectively electrically connected to one of the first superconducting electrode 204 and the second superconducting electrode 206 in the arrangement of FIG. 2. Similarly, the first superconductor 304 and the second superconductor 306 may each be respectively electrically connected to different plates of the capacitor 106 in the arrangement of FIG. 1.

The Josephson junction 104 may be fabricated using any suitable fabrication technique. For example, electron beam lithography may be used to form suitable patterns in materials provided on the substrate 302 in order to manufacture the Josephson junction 104.

As was described above, a Josephson junction 104 is a nonlinear inductive element. When implemented in a superconducting qubit 102, 202, a Josephson junction 104 may in practice serve to create a distinct difference between energy levels of the superconducting qubit 102, 202.

Properties of a Josephson junction 104 included in a qubit 102, 202 have a significant impact on the resonance frequency of the qubit 102, 202. For example, the resonance frequency of a qubit 102, 202 may depend, at least in part, on the resistance of the Josephson junction 104. Furthermore, as was explained above, fabrication of a Josephson junction 104 can be subject to variance such that a given fabricated Josephson junction 104 may have properties which vary from target or design parameters with which the Josephson junction 104 was fabricated. For example, the resistance of fabricated Josephson junctions 104 may be subject to variance. Consequently a resonance frequency of fabricated qubits 102, 202 which include a Josephson junction 104 may be subject to dispersion.

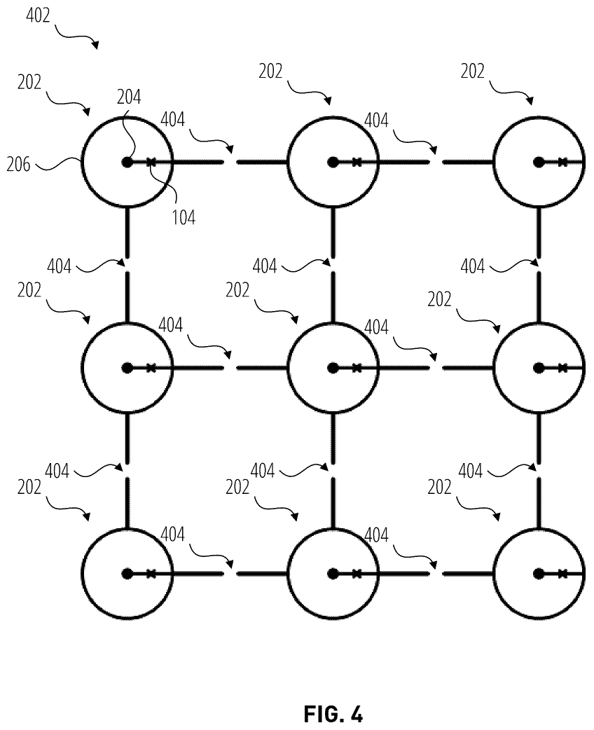

By way of illustrative example, a plurality of qubits 102, 202 each including a Josephson junction 104 may be fabricated on a single substrate 302 or chip to form a quantum information processor. FIG. 4 is a schematic illustration of a quantum information processor 402 comprising a plurality of qubits 202. In the example illustrated in FIG. 4 the qubits 202 are of the form of the qubit 202 described above with reference to FIG. 2. That is, each qubit 202 comprises a Josephson junction 104 connected between a first superconducting electrode 204 and a second superconducting electrode 206, arranged to be coaxial with respect to each other (these components are not explicitly labelled in FIG. 4). In the example of FIG. 4, neighbouring qubits 202 are coupled to each other by capacitors 404. In particular, the second superconducting electrodes 206 (the outer electrode in each qubit 202) of neighbouring qubits 202 are connected to each other by capacitors 404. The coupling of neighbouring qubits 102 by capacitors 106 allows for interactions between the qubits 202 as may be utilised when carrying out quantum computations using the quantum information processor 402.

The arrangement of FIG. 4 is provided merely as an illustrative example and it will be appreciated that other examples of quantum information processors may include different numbers of qubits, different arrangements of qubits and/or different types of qubits to those illustrated in FIG. 4.

In some examples, a quantum information processor 402 comprising a plurality of qubits 202 may be fabricated in such a way that each of the qubits 202 and Josephson junctions 104 are fabricated according to the same design parameters. For example, the target or design parameters for each qubit 202 may be the same such that under a perfect manufacturing process, each qubit 202 would have identical parameters (for example, dimensions, resistances and resonance frequencies). In practice, variance in the fabrication of Josephson junctions 104 may result in a dispersion in properties (for example, resonance frequencies) of the qubits 202 even though they are each fabricated according to the same design parameters. For example, in a typical fabrication process, variance in the fabrication of Josephson junctions 104 may result in the resistances of a plurality of fabricated Josephson junctions 104 (each fabricated according to the same design parameters) having a standard deviation of approximately 2-3% of the mean resistance value. This may translate into a spread of qubit 202 frequencies having a standard deviation of approximately 1-1.5%.

Dispersion in qubit 202 frequencies may degrade the performance of a quantum information processor 402 incorporating qubits 202 comprising Josephson junctions 104. For example, the quantum information processor 402 may be designed such that each qubit 202 has the same resonance frequency. Such a design may allow a single source of microwave radiation having a frequency corresponding to the frequency of the qubits 202 to be used to control the states of the qubits 202 and drive transitions between energy levels of the qubits 202. However, dispersion in the frequency of the qubits 202 introduced by variance in the fabrication of Josephson junctions 104 included in the qubits 202 may affect the efficiency with which different qubits 202 can be driven with a single microwave radiation source. Dispersion in the frequency of qubits 202 may additionally or alternatively cause one or more further disadvantageous effects such as random crosstalk, frequency collisions and slow entangling gates.

Whilst an example has been described above in which a quantum information processor 402 is designed to include qubits 202 having the same resonance frequency, in other examples a quantum information processor 402 may be designed such that different qubits 202 have different frequencies. For example, neighbouring qubits 202 may be designed to have different frequencies in order to reduce any crosstalk between neighbouring qubits 202. In such examples, dispersion in the frequencies of fabricated qubits 202 from their design frequencies may result in crosstalk between neighbouring qubits 202.

In general it may be desirable to be able to more accurately control the frequencies of fabricated qubits 102, 202. For example, in implementations in which a quantum information processor 402 is designed to include qubits 202 having the same frequency, it may be desirable to adjust the frequencies of at least some of the qubits 202 in order to reduce any dispersion in the frequencies of the qubits 202. Additionally or alternatively, in implementations in which a quantum information processor 402 is designed to include qubits 202 having different frequencies, it me be desirable to adjust the frequencies of at least some of the qubits 202 in order to reduce any difference between the qubit 202 frequencies and their design frequencies. In general, improved control over qubit 102, 202 frequencies may reduce or mitigate effects such as crosstalk, frequency collisions and slow entangling gates and may generally improve fault tolerance in a quantum computer.

It has been found that the resistance of a Josephson junction 104 can be adjusted by directing an electron beam to heat the Josephson junction 104. An example of an electron beam 110 being directed to heat a Josephson junction 104 is shown schematically in FIG. 1, FIG. 2 and FIG. 3. The electron beam 110 may be generated by an electron source 108 such as an electron gun.

FIG. 5 is a flowchart of a method 500 of adjusting a frequency of a qubit 102, 202 according to examples disclosed herein. The method 500 of FIG. 5 may be carried out as a post-fabrication process. That is, the method 500 of FIG. 5 may be carried out to adjust the frequency of a qubit 102, 202 after the qubit 102, 202 has been fabricated.

At step 502 an electron beam 110 is directed to heat the Josephson junction 104. The electron beam 110 may be generated and directed by an electron source 108, such as an electron gun. The electron source 108 may use any suitable form of electron beam generation process such as thermionic emission or field electron emission. The electron source 108 may further be configured to focus and direct the electron beam 110 to heat the Josephson junction 104. For example, the electron source 108 may include one or more electrostatic or magnetic lenses arranged to focus and/or direct the electron beam 110 to heat the Josephson junction 104.

It will be appreciated that in order to suitably direct an electron beam 110 to heat a Josephson junction 104, the Josephson junction 104 and the electron source 108 may be placed under vacuum pressure conditions.

According to at least some examples, an electron beam lithography apparatus may be used to generate and direct an electron beam 110 to heat a Josephson junction 104. Conveniently, an electron beam lithography apparatus may include (in addition to an electron source 108) apparatus for aligning a generated electron beam 110 relative to a Josephson junction 104 on which the electron beam 110 is to be incident. For example, an electron beam lithography apparatus may include a stage for supporting a substrate 302 on which a Josephson junction 104 is situated and aligning the substrate 302 relative to the electron beam 110 such that the electron beam 110 is incident on the Josephson junction 104. An electron beam lithography apparatus may further include components for generating vacuum pressure conditions in which an electron source 108 and the Josephson junction 104 may be situated.

In other examples, other forms of apparatus may be used to direct an electron beam 110 to heat a Josephson junction 104. For example, a scanning electron microscope may be used to direct an electron beam to heat a Josephson junction 104.

The electron beam 110 is configured to heat the Josephson junction 104. For example, the electron beam 110 is generated with a suitable current such that the electrons serve to heat the Josephson junction. In particular, the electron beam 110 may be configured to heat the Josephson junction 104 so as to induce material changes in at least one of the components of the Josephson junction 104. In at least some examples, the electron beam 110 may induce a temperature change of the order of between about 50 degrees Celsius to about 1000 degrees Celsius or more.

In at least some examples, the electron beam 110 may be generated with a current which is greater than approximately 0.1 nano-amp (nA). For example, the electron beam 110 may be generated with a current which is greater than approximately 1 nA. In at least some examples, the electron beam 110 may be generated with a current which is less than approximately 1000 nA. For example, the electron beam 110 may be generated with a current which is less than approximately 500 nA and may be generated with a current which is less than approximately 200 nA.

In some examples, the electron beam 110 may be directed to be directly incident on at least one component of the Josephson junction 104. In such examples, the electron beam 110 may cause at least some direct heating of the Josephson junction 104 since it is directly incident on the Josephson junction 104.

In some examples, the electron beam 110 may be directed such that it is not directly incident on the Josephson junction 104. In such examples, the electron beam 110 may cause indirect heating of the Josephson junction 104 by heating another component or material, from which heat is conducted to heat the Josephson junction 104. For example, the electron beam 110 may be directed to be incident on a portion of the substrate 302 which is sufficiently close to the Josephson junction 104 that it is thermally coupled to the Josephson junction 104. Heating of the portion of the substrate 302 by the electron beam 108 causes heating of the Josephson junction 104 by heat conduction from the heated portion of the substrate 302.

Indirect heating of a Josephson junction 104, (for example, by directing the electron beam 110 to be incident on a portion of the substrate 302 in proximity to the Josephson junction 104) may reduce a risk of causing damage, since it is possible that direct heating may, under at least some conditions, cause damage to the Josephson junction which may adversely affect its performance.

The electron beam 110 may be directed to heat the Josephson junction 104 for an exposure time period to deliver a charge dose to the component on which electron beam 110 is incident (e.g., the Josephson junction 104 itself or a component which is thermally coupled to the Josephson junction 104). The charge dose which is delivered is sufficient to heat the Josephson junction 104. For example, the charge dose which is delivered may be sufficient to heat the Josephson junction 104 so as to induce material changes in at least one of the components of the Josephson junction 104. In some examples, the electron beam 110 may be directed to heat the Josephson junction 104 for a single continuous exposure time period. Such a technique of directing an electron beam 110 to heat a Josephson junction 104 for a single continuous exposure time period may be referred to herein as delivering a single shot of a charge dose to the Josephson junction 104.

In some examples, a plurality of pulses of the electron beam 110 may be directed to heat the Josephson junction 104 for a plurality of successive exposure time periods. The plurality of successive exposure time periods may be separated by time periods in which no electron beam 110 is directed to heat the Josephson junction 104. Such a technique of directing pulses of an electron beam 110 to heat a Josephson junction 104 for multiple successive exposure time periods (separated by time periods in which no electron beam 110 is directed to heat the Josephson junction 104) may be referred to herein as delivering multiple shots of a charge dose to the Josephson junction 104.

In some examples, a plurality of pulses of the electron beam 110 may be directed to be incident on a plurality of different positions. For example, a plurality of pulses of the electron beam 110 may be directed to be incident on a plurality of different positions on the Josephson junction 104 itself and/or on the substrate 302 in proximity to the Josephson junction 104.

In some examples, a plurality of pulses of the electron beam 110 may be directed to be incident on a plurality of different positions to define an exposure pattern. The exposure pattern may, for example, comprise a grid of positions at which the electron beam 110 is directed to be incident. The positions at which the electron beam 110 are directed to be incident may be controlled in order to control the heating which is provided to the Josephson junction 104.

In some examples, an electron beam 110 may be directed to heat a Josephson junction 104 (for one or more exposure time periods) so as to deliver a charge dose which is greater than approximately 10 micro Coulombs per centimetre squared (μC/cm²). For example, a charge dose which is greater than approximately 50 μC/cm² may be delivered to a Josephson junction 104 and/or a component (such as the substrate 302) which is thermally coupled to the Josephson junction 104. In some examples, an electron beam 110 may be directed to heat a Josephson junction 104 (for one or more exposure time periods) so as to deliver a charge dose which is less than approximately 5000 μC/cm². For example, a charge dose which is less than approximately 2000 μC/cm² may be delivered to a Josephson junction 104 and/or a component (such as the substrate 302) which is thermally coupled to the Josephson junction 104.

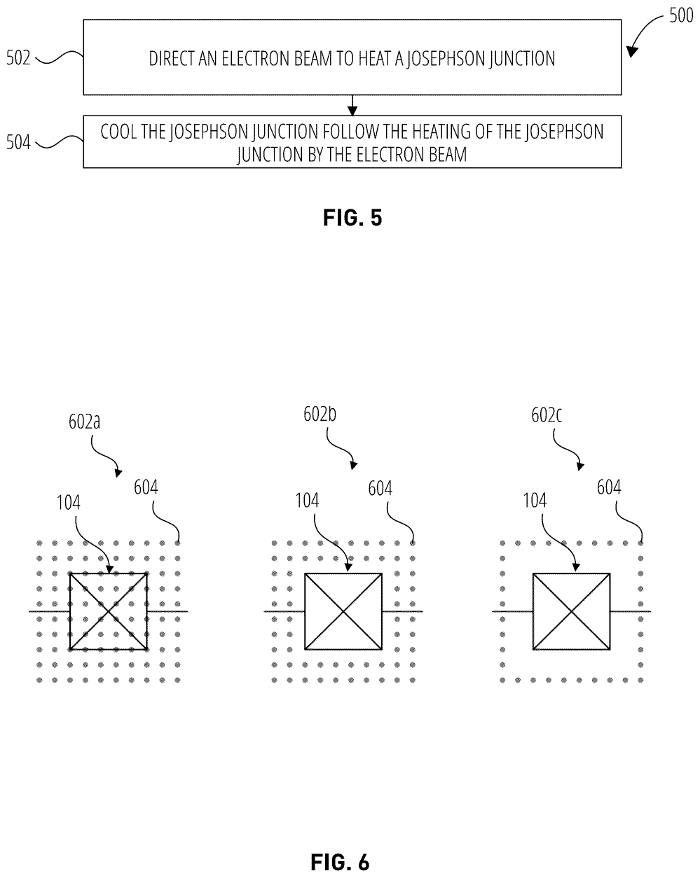

FIG. 6 is a schematic illustration of a plurality of different exposure patterns 602a, 602b, 602c to which a Josephson junction 104 may be subjected. Each of the exposure patterns 602a, 602b and 602c shown in FIG. 6 comprise a plurality of exposure spots 604. Each exposure spot 604 is represented by a grey circle in FIG. 6. For ease of illustration, only some of the exposure spots 604 are explicitly labelled in FIG. 6. Each exposure spot 604 represents a position at which an electron beam 110 is directed to be incident (e.g., by an electron source 108). An electron beam 110 may be directed to be incident on each exposure spot 604 which forms an exposure pattern 602a, 602b, 602c at the same or different times. For example, an exposure pattern 602a, 602b, 602c may be formed by using a single electron source 108 to direct an electron beam 110 to be incident on each exposure spot 604 successively and at different times. Alternatively, a plurality of electron sources 108 may be used to direct a plurality of electron beams 110 to be incident on different exposure spots 604 in an exposure pattern 602a, 602b, 602c at the same time.

In the examples, shown in FIG. 6, each exposure pattern 602a, 602b, 602c is centred on a Josephson junction 104. However, as will be further described below, exposure patterns 602a, 602b, 602c may be directed to be incident on locations which are not necessarily centered on a Josephson junction 104. For example, an exposure pattern 602a, 602b, 602c may be directed to be incident on a location which is separated from but thermally coupled with a Josephson junction 104.

A first example of an exposure pattern 602a is shown in the left-most region of FIG. 6. The first example of an exposure pattern 602a comprises a substantially uniform grid of exposure spots 604. The first example of an exposure pattern 602a includes at least some exposure spots 604 which are positioned on a portion of the Josephson junction 104 such that directing an electron beam 110 to be incident on at least some of the exposure spots 604 will lead to direct heating of at least a portion of the Josephson junction 104. The first example of an exposure pattern 602a further includes at least some exposure spots 604 which are not directly positioned on the Josephson junction 104 but are in proximity to the Josephson junction 104. Directing an electron beam 110 to be incident on such exposure spots 604 may comprise directing the electron beam 110 to be incident on a component (such as a portion of a substrate 302) which is thermally coupled to the Josephson junction 104 so as to cause indirect heating of the Josephson junction 104. An exposure pattern 602a having the general form of the first example of an exposure pattern 602a may be referred to herein as a fully closed exposure pattern.

A second example of an exposure pattern 602b is shown in the central region of FIG. 6. The second example of an exposure pattern 602b is formed of exposure spots 604 which enclose the Josephson junction 104. The second example of the exposure pattern 602b includes exposure spots 604 which are not directly positioned on the Josephson junction 104 and does not include exposure spots 604 which are positioned on the Josephson junction 104 itself. The second example of an exposure pattern 602b, therefore leads to indirect heating of the Josephson junction 104. As can be seen in FIG. 6, the second example of an exposure pattern 602b is formed of exposure spots 604 which trace out two loops (in the form of squares in the depicted example), of different sizes but which both enclose the Josephson junction 104. An exposure pattern 602b having the general form of the second example of an exposure pattern 602b may be referred to herein as a thick loop exposure pattern 602b.

A third example of an exposure pattern 602c is shown in the right-most region of FIG. 6. Similarly to the second example of an exposure pattern 602b, the third example of an exposure pattern 602c is formed of exposure spots 604 which surround the Josephson junction 104. The third example of an exposure pattern 602c similarly includes exposure spots 604 which are not directly positioned on the Josephson junction 104 and does not include exposure spots 604 which are positioned on the Josephson junction 104. The third example of an exposure pattern 602 therefore leads to indirect heating of the Josephson junction 104. The third example of the exposure pattern 602c differs from the second example of an exposure pattern 602b in that it includes exposure spots 604 which trace out a single loop (in the form of a square in the depicted example) which encloses the Josephson junction 104 (as opposed to two loops as in the second example of an exposure pattern 602b). The third example of an exposure pattern 602b therefore generally includes less exposure spots 604 than the second example of an exposure pattern 602b. An exposure pattern 602c having the general form of the third example of an exposure pattern 602c may be referred to herein as a thin loop exposure pattern.

Exposure patterns of the form of the second example of an exposure pattern 602b and the third example of an exposure pattern 602c are described herein as being arranged to enclose a Josephson junction 104 and as being arranged to form a loop of exposure spots 604. It will be appreciated (as can be seen in FIG. 6) that there are gaps in between adjacent exposure spots 604 and as such the exposure spots 604 do not form a fully closed loop. However, such exposure patterns are still considered to be arranged in a loop and to generally enclose the Josephson junction 104.

Three different examples of exposure patterns 602a, 602b, 602c have been described with reference to FIG. 6. The second 602b and third 602c examples are arranged to cause indirect heating of a Josephson junction 104 only, whereas the first 602a example is arranged to cause both direct and indirect heating of a Josephson junction 104. As was explained above, indirect heating of a Josephson junction 104 (when compared to direct heating) may reduce a risk of causing damage to the Josephson junction 104, since it is possible that direct heating may, under at least some conditions, cause damage to a Josephson junction, which may adversely affect its performance. Exposure patterns of the form of the second 602b and third 602c exposure patterns may therefore, in at least some examples, be advantageously used to cause heating of a Josephson junction 104 without directing an electron beam 110 to be directly incident on the Josephson junction 104 (which might in some examples risk causing damage to the Josephson junction 104). An exposure pattern 602b, 602c which form a loop enclosing the Josephson junction 104 (as in the second 602b and third 602c examples) may cause relatively uniform heating of the Josephson junction 104 since indirect heating is delivered on all sides of the Josephson junction 104.

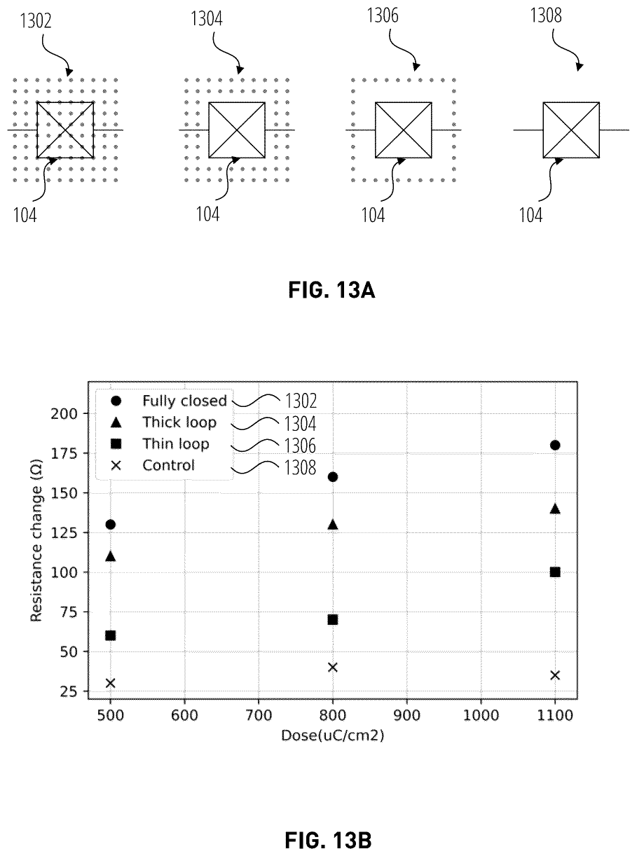

As will be demonstrated in results presented below with reference to FIG. 13A and FIG. 13B, the use of exposure patterns 602a, 602b, 602c comprising a plurality of exposure spots 604 may provide a further degree of control over an amount by which a Josephson junction 104 is heated and thus by how much its resistance is adjusted. In at least some examples, different forms of exposure pattern may be used in order to cause different changes in resistance of a Josephson junction 104.

The example exposure patterns shown in FIG. 6 are presented as examples only. In other examples, one or more electron beams 110 may be directed to form exposure patterns including a plurality of exposure spots 604 in different arrangements to those shown in FIG. 6.

As was explained above, in at least some examples, a plurality of pulses of an electron beam 110 may be directed to be incident on a plurality of different positions (exposure spots 604) so as to heat a Josephson junction 104. The plurality of different positions may define an exposure pattern, which may be controlled in order to control the heating which is delivered to the Josephson junction 104. In some examples, a distance between position(s) (e.g., exposure spots 604) at which an electron beam 110 is directed to be incident and a Josephson junction 104 may be controlled in order to control heating which is delivered to a Josephson junction 104.

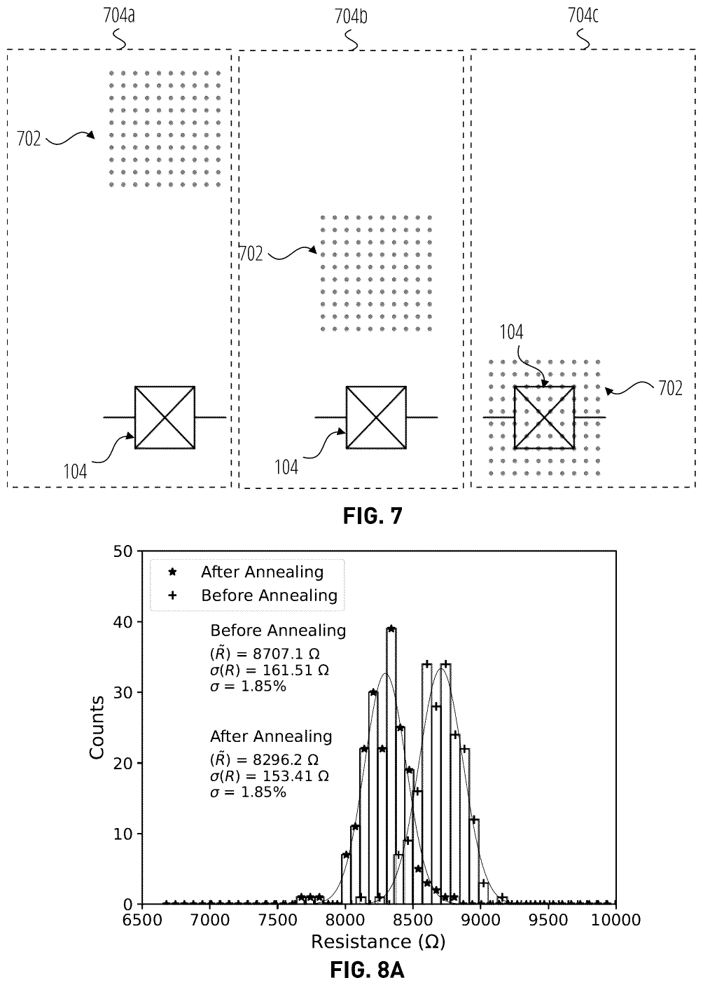

FIG. 7 is a schematic illustration of exposure patterns 702 at three different distances from a Josephson junction 104 to be heated. In the examples depicted in FIG. 7, a fully closed exposure pattern (similar to the first example exposure pattern 602a described above with reference to FIG. 6) comprising a grid of exposure spots is used. In a first exposure example 704a shown in the panel labelled 704a in FIG. 7, an exposure pattern 702 is separated from a Josephson junction 104 by a first distance. The first distance may be such that directing one or more electron beams 110 to form the exposure pattern 702 delivers indirect heating to the Josephson junction 104 by way of heat conduction from the positions (exposure spots) at which the electron beam(s) is incident. In some examples, the first distance may be less than about 100 micrometres (μm). For example, the first distance may be less than about 50 μm and may be approximately 30 μm.

In a second exposure example 704b shown in the panel labelled 704b in FIG. 7, an exposure pattern 702 is separated from a Josephson junction 104 by a second distance which is less than the first distance used in the first exposure example 704a. It will be appreciated that the smaller separation distance between the exposure pattern 702 and the Josephson junction 104 may cause the Josephson junction 104 to be heated to a greater extent using the second exposure example 704b than the first exposure example 704a (assuming that all other properties, such as electron beam current, charge dose and exposure time remain the same).

In a third exposure example 704c shown in the panel labelled 704b in FIG. 7, an exposure pattern 702 may be centered on a Josephson junction 104 such that at least some of the exposure spots which form the exposure pattern correspond to an electron beam 110 being directly incident on a Josephson junction 104. The third exposure example 704c may therefore include at least some direct heating of the Josephson junction 104. It will be appreciated that the third exposure example 704c may cause the Josephson junction 104 to be heated to a greater extent than the first exposure example 704a or the second exposure example 704b (assuming that all other properties, such as electron beam current, charge dose and exposure time remain the same).

As was explained above, an amount of heating which is delivered to a Josephson junction 104 may depend, at least in part, on a separation between a position on which an electron beam 110 is directed to be incident (which may, for example, include a plurality of exposure spots 604 forming an exposure pattern 702) and the Josephson junction 104. A separation between one or more positions (exposure spots 604) at which an electron beam 110 is directed to be incident and a Josephson junction 104 may therefore be controlled in order to control an amount of heating which is delivered to a Josephson junction 104. Such control may be used to control a change in resistance of the Josephson junction 104 which is caused by the heating.

Returning again to the method 500 of FIG. 5, at step 504, the Josephson junction 104 is cooled following the heating of the Josephson junction 104 by the electron beam 110. Cooling the Josephson junction 104 following the heating of the Josephson junction 104 by the electron beam 110 may comprise not directing an electron beam 110 to heat the Josephson junction 104 (e.g., by turning off the electron beam 110, moving the electron beam 110 away from the Josephson junction 104 and/or moving the Josephson junction 104 away from the path of the electron beam 110) and allowing the Josephson junction 104 to cool under the ambient temperature conditions in which it is situated. That is, cooling the Josephson junction 104 may not necessarily comprise delivering any active cooling of the Josephson junction 104 and may simply comprise allowing the Josephson junction 104 to cool following the heating of the Josephson junction 104 by the electron beam 110. However, in some examples, cooling the Josephson junction 104 may comprise applying active cooling to the Josephson junction 104.

It has been found that heating a Josephson junction 104 by directing an electron beam 110 to heat the Josephson junction 104 and then cooling the Josephson junction 104 (as was described above with reference to steps 502 and 504 of the method 500 of FIG. 5) can be used to alter the resistance of the Josephson junction 104. Consequently, the frequency of a qubit 102, 202 in which the Josephson junction 104 is incorporated may be adjusted through heating the Josephson junction 104 with an electron beam 110. Without wishing to be tied to any particular theory, it is thought that heating a Josephson junction 104 with an electron beam 110 serves to anneal at least one of the components of the Josephson junction 104 to change a material property of the at least one component. It is thought that this change in material property of the least one component of the Josephson junction 104 brings about a change in the resistance of the Josephson junction 104. A process of heating a Josephson junction 104 by directing an electron beam 110 to heat the Josephson junction 104 and cooling the Josephson junction 104 (as was described above with reference to steps 502 and 504 of the method 500 of FIG. 5) may be referred to herein as electron beam annealing of a Josephson junction 104.

It has been found that an electron beam 110 provides a highly controllable and localised method of heating a Josephson junction 104 so as to adjust a frequency of a qubit 102, 202 in which the Josephson junction 104 is incorporated. An electron beam 110 which is directed to heat a Josephson junction 104 by a suitable electron source 108 may have a beam diameter which is less than approximately 200 nm, and may be less than approximately 100 nm. In at least some examples, the electron beam 110 may have a beam diameter of less than about 50 nm. For example, the electron beam 110 may have a beam diameter of the order of about 10-50 nanometres (nm). By way of comparison a Josephson junction 104 may have approximate dimensions of the order of about 50 nm to 500 nm.

In general the beam diameter of an electron beam 110 may be smaller than the diameter of a laser beam, which might be used in a thermal annealing process. For example, a typical laser beam having a wavelength of approximately 500 nm might be focused to have a spot size of diameter of the order of 10 micrometres (μm). The beam diameter of a laser beam may therefore be several orders of magnitude greater than a beam diameter of an electron beam 110.

An electron beam 110 having a small beam diameter (e.g., less than about 200 nm, less than about 100 nm, or even less than about 50 nm) may be particularly advantageous for providing highly localised and/or highly controllable heating to a Josephson junction 104. For example, in a typical quantum information processor 402, neighbouring qubits 202 (and neighbouring Josephson junctions 104) may have a separation between them of the order of a few hundred micrometres or about a millimetre (mm). In order to provide an accurately controllable adjustment of qubit frequency it may be desirable to heat a Josephson junctions included in a qubit independently of other Josephson junctions 104 included in other qubits. For example, it may be desirable to heat a Josephson junction 104 included in a first qubit independently and without causing any significant heating to other nearby Josephson junctions (so as to have no significant impact on the resistance of the other nearby Josephson junctions). The relatively small beam diameter of an electron beam 110 (when compared, for example to the beam diameter of a laser beam) may advantageously provide highly localised heating to a Josephson junction 104 and may allow for independent control of the resistance of a Josephson junction (and correspondingly independent control of qubit frequency) without significantly altering the resistance of other nearby Josephson junctions 104 (and correspondingly without significantly altering the frequency of other nearby qubits).

In some implementations, a qubit may include a plurality of Josephson junctions 104. For example, a qubit may include two Josephson junctions 104. In some examples, a qubit may include a first superconducting electrode 204 and a second superconducting electrode 206 in a coaxial arrangement, as shown in FIG. 2. The qubit may further include a plurality of Josephson junctions 104 each connected between the first superconducting electrode 204 and the second superconducting electrode 206. It will be appreciated that in examples in which a qubit includes a plurality of Josephson junctions 104 a separation between neighbouring Josephson junctions 104 may be less than examples in which a qubit includes a single Josephson junction 104. For example, a separation between Josephson junctions 104 which form part of the same qubit may be less than a separation between Josephson junctions 104 forming part of neighbouring qubits. Additionally or alternatively, the inclusion of multiple Josephson junctions 104 per qubit may reduce a separation between Josephson junctions 104 forming part of neighbouring qubits.

In examples, in which a qubit includes a plurality of Josephson junctions 104 delivering highly localised heating to a Josephson junction 104 (by directing an electron beam 110 to heat the Josephson junction 104) may be particularly advantageous in allowing for independent heating of Josephson junctions 104 and without providing any significant heating to nearby Josephson junctions 104.

The relatively small beam diameter of an electron beam 110 (for example, when compared to the diameter of a laser beam) may also allow an exposure pattern (for example comprising a plurality of different positions on which the electron beam 110 is directed to be incident) to be precisely controlled in order to control the heating which is provided to the Josephson junction 104.

As was explained above with reference to FIG. 6 and FIG. 7, the heating of a Josephson junction and the change of resistance which is induced by the heating may be controlled by controlling additional factors such as an exposure pattern and/or a separation between a position(s) of an electron beam 110 and the Josephson junction 104. The relatively small beam diameter of an electron beam 110 allows for accurate and precise control of such additional factors in a way which would not be possible using other methods. For example, as was described above with reference to FIG. 6, different exposure patterns may be used to control heating of a Josephson junction 104. In some examples, an exposure pattern in the form of a loop enclosing a Josephson junction 104 may be used, which allows for localised and controllable indirect heating of the Josephson junction 104. It will be appreciated that such control and heating may not be possible when heating a Josephson junction using other methods (such as using a laser beam).

As has been described in detail above, an electron beam 110 may be used to provide localised heating to a Josephson junction 104 so as to alter the resistance of the Josephson junction 104 and correspondingly adjust a frequency of a qubit 102, 202 in which the Josephson junction 104 is incorporated (which may be referred to as electron beam annealing). The frequency of a qubit 102, 202 in which a Josephson junction 104 is incorporated may be inversely proportional to the resistance of the Josephson junction 104. That is, an increase in the resistance of a Josephson junction 104 may cause a decrease in the frequency of the qubit 102, 202, which is proportional to the increase in the resistance. A decrease in the resistance of a Josephson junction 104 may cause an increase in the frequency of the qubit 102, 202, which is proportional to the decrease in the resistance.

The inventors have successfully demonstrated that using an electron beam 110 to provide localised heating to a Josephson junction 104 to alter the resistance of the Josephson junction 104 and correspondingly adjust a frequency of a qubit 102, 202, does not adversely affect a coherence time of the qubit. A coherence time of a qubit is a measure of a duration of time that a qubit can retains its information and can be manipulated to perform quantum computations. The inventors have demonstrated that after subjecting qubits to electron beam annealing processes as described herein, the coherence time of the qubits was not adversely affected and the qubits remained as high coherence qubits (having a relatively long coherence time).

It has been found that directing an electron beam 110 to heat a Josephson junction 104 as described above (for example, with reference to the method of FIG. 5) can be used to selectively increase or decrease the resistance of the Josephson junction 104. Correspondingly, the frequency of a qubit 102, 202 including a Josephson junction 104 can be selectively decreased or increased. In particular, it has been found that electron beam 110 currents which are greater than a threshold current and/or charge doses greater than a threshold dose serve to decrease the resistance of a Josephson junction 104 (and correspondingly increase qubit frequency). Correspondingly, electron beam 110 currents which are less than the threshold current and/or charge doses which are less than the threshold dose serve to increase the resistance of a Josephson junction 104 (and correspondingly decrease qubit frequency).

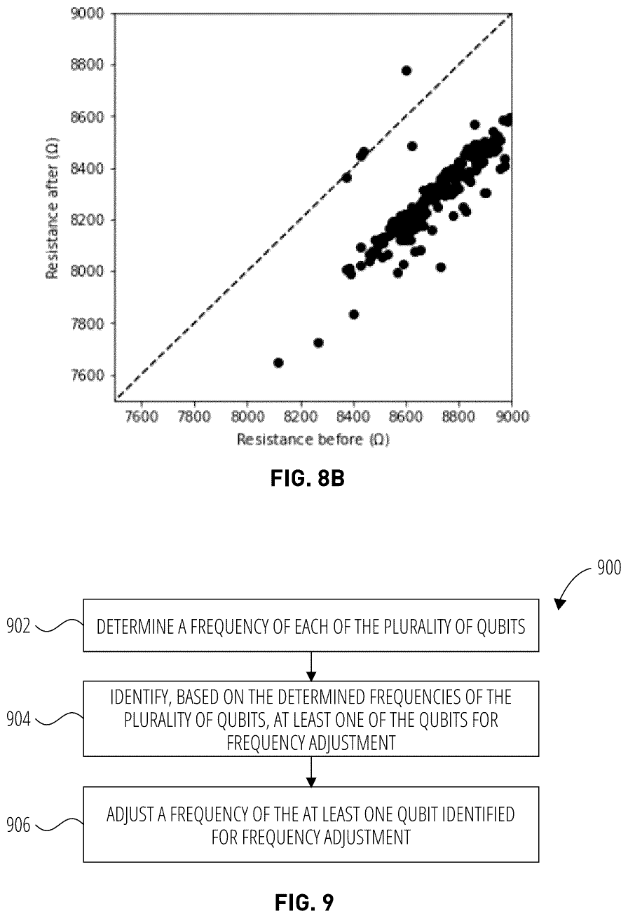

The current and/or charge dose threshold (below which an increase in resistance occurs and above which a decrease in resistance occurs) will depend on properties of a given Josephson junction 104 and is not fixed for all Josephson junctions 104. By way of illustrative example only, results are presented in FIG. 8A and FIG. 8B showing that electron beam annealing can be used to decrease the resistance of Josephson junctions 104.

FIG. 8A is a histogram representation of the resistance (in Ohms) of a group of 192 Josephson junctions 104. The group of 192 Josephson junctions were each fabricated with the same design parameters so as to have the same dimensions. Under a perfect manufacturing process each of the 192 Josephson junctions would therefore have the same resistance. However, as can be seen in FIG. 8A variance in the manufacturing of Josephson junctions results in a dispersion in the resistance of the Josephson junctions. In particular, resistances of the 192 Josephson junctions after fabrication have a standard deviation of approximately 1.85% of the mean resistance.

In order to demonstrate that an electron beam 110 can be used to decrease the resistance of Josephson junctions, each of the 192 Josephson junctions were exposed to a 100 nA electron beam 110 to deliver a charge dose of 300-1300 μC/cm². A corresponding histogram of the resistances of the same group of 192 Josephson junctions after performing an electron beam annealing process with a 100 nA electron beam is also shown in FIG. 8A. As can be clearly seen in FIG. 8A a 100 nA electron beam annealing process serves to decrease the mean resistance of the Josephson junctions by approximately 411 Ohms. It can also be seen from FIG. 8B that the dispersion in resistances is relatively unchanged.

FIG. 8B is a scatter graph of the resistances of the same 192 Josephson junctions which are shown in FIG. 8A. In FIG. 8B the horizontal axis represents the resistances of the Josephson junctions after fabrication and before being subjected to the electron beam annealing process described above with reference to FIG. 8A. The vertical axis of FIG. 8B represents the resistances of the Josephson junctions after being subjected to the electron beam annealing process described above with reference to FIG. 8A. FIG. 8B provides a further illustration of the increase in resistance of the Josephson junctions which is caused by the electron beam annealing process.

Electron beam annealing processes were described above, for example, with reference to FIG. 8A, and FIG. 8B in which the same electron beam annealing process is applied to each of a group of Josephson junctions. Such a process has been shown to increase or decrease the mean resistance of the Josephson junctions and to have little influence on the dispersion of the frequency of the Josephson junctions.

In some examples, an electron beam annealing process may be applied selectively to a group of Josephson junctions. For example, electron beam annealing may only be performed on a subset of a group of Josephson junctions. Such methods may, for example, be applied in order to reduce a dispersion of resistances of the group of Josephson junctions. Correspondingly a dispersion of frequencies of qubits in which the Josephson junctions are incorporated may be reduced.

FIG. 9 is a flowchart of an example method 900 of adjusting qubit frequencies of a quantum information processor comprising a plurality of qubits. Each qubit of the quantum information processor includes at least one Josephson junction. The quantum information processor 402 may, for example, have any of the features described above with reference to the quantum information processor 402 shown in FIG. 4.

At step 902 of the method 900 of FIG. 9 a frequency of each of the plurality of qubits is determined. The frequencies of each of the plurality of qubits may be directly measured during operation as qubits. Alternatively, one or more properties of the qubits may be measured in order to determine a value indicative of the qubit frequencies. For example, a resistance of Josephson junctions included in each of the qubits may be measured. Such a measurement of resistance may conveniently be carried out without cooling the qubits to sufficiently cold temperatures that they exhibit superconductivity. Measurements of the resistances of the Josephson junctions may be used to determine the frequencies of the qubits. Alternatively, the measured resistances themselves may serve as determined values indicative of the frequencies of the qubits. That is, resistance values may be used as a proxy for frequency values given the well-understood inverse proportionality between these variables.

At step 904 of the method 900 of FIG. 9 at least one of the qubits of the quantum information processor is identified for frequency adjustment. The at least one qubit for frequency adjustment is identified based on the determined frequencies of the plurality of qubits. In at least some examples, identifying the at least one of the plurality of qubits for frequency adjustment comprises identifying at least one of the plurality of qubits having a frequency which can be adjusted to reduce a dispersion of the frequencies associated with each of the plurality of qubits. In some examples, identifying the at least one of the plurality of qubits for frequency adjustment comprises identifying at least one of the plurality of qubits having a frequency which is different from a target or design frequency for that qubit.

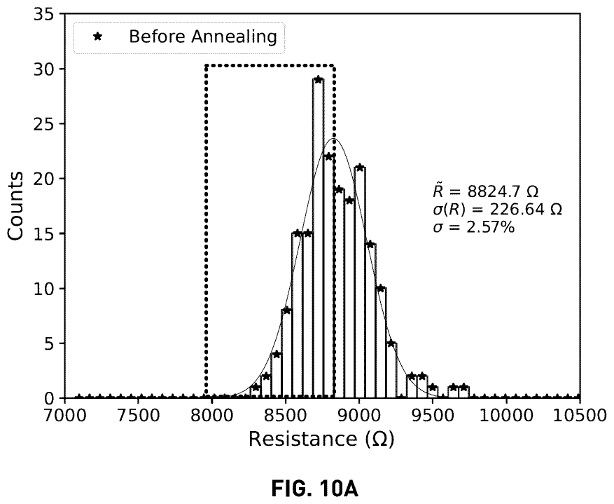

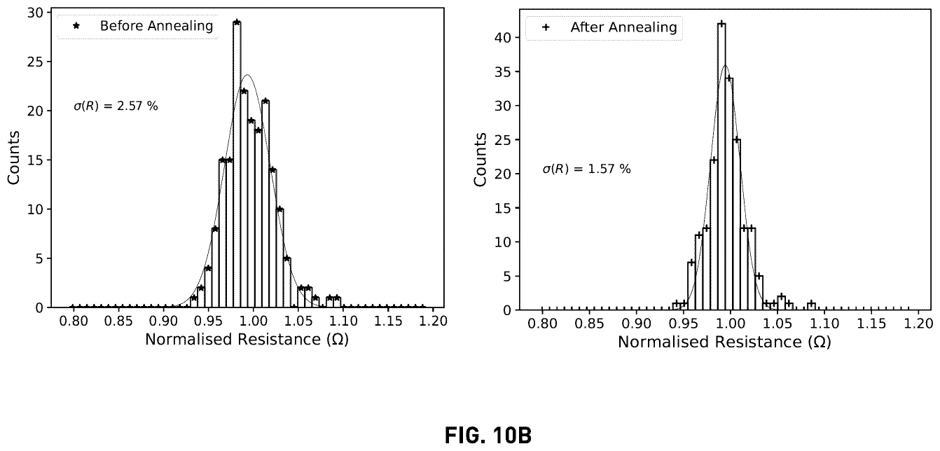

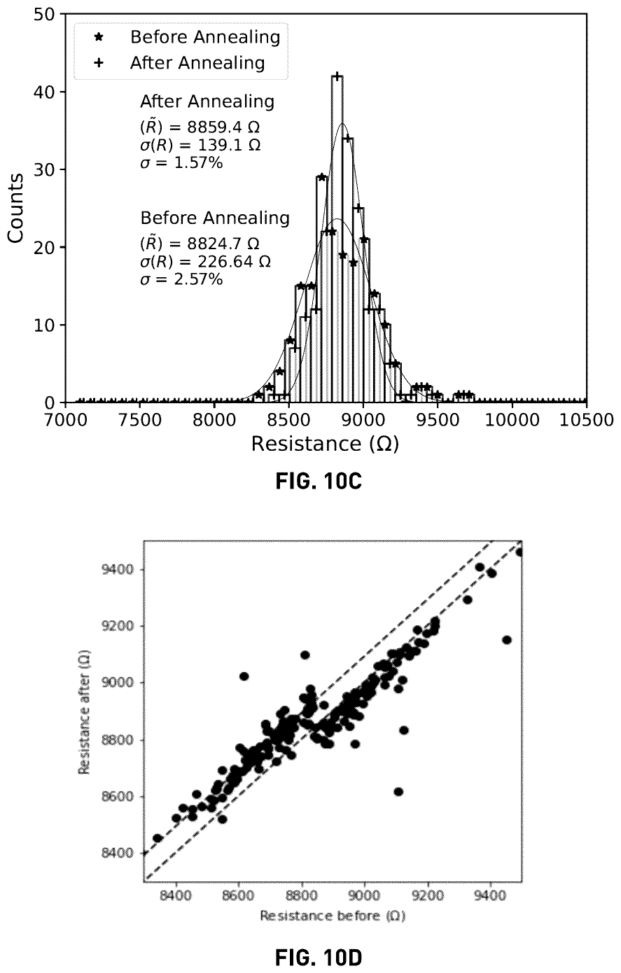

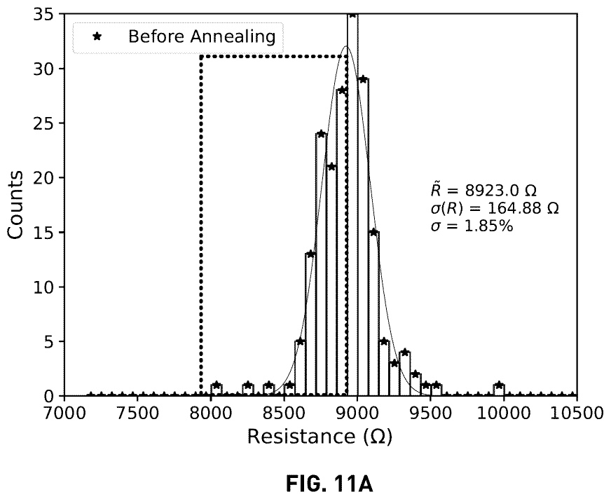

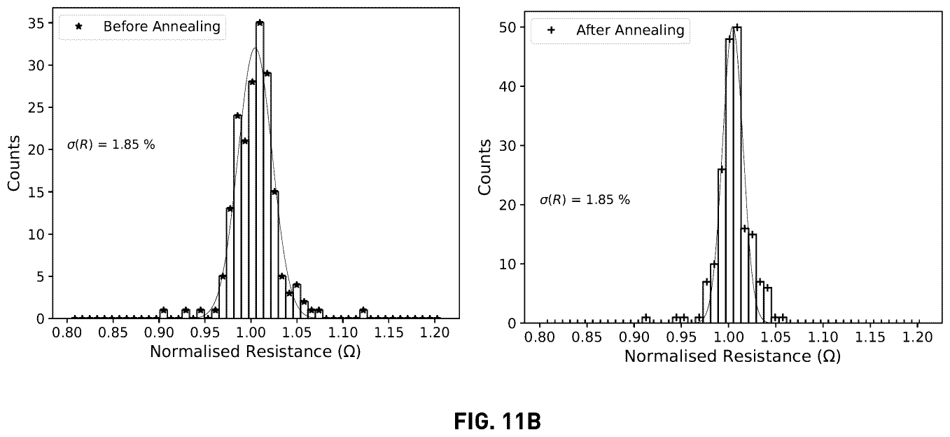

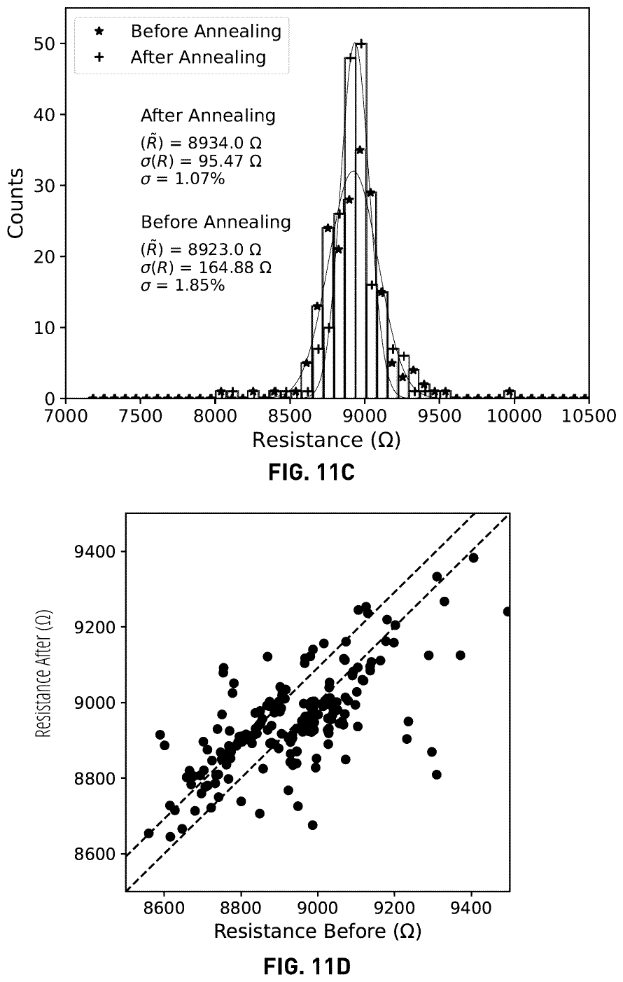

By way of illustrative example, a histogram of the resistances (in Ohms) of a first group of Josephson junctions 104 is shown in FIG. 10A. Each of the first group of Josephson junctions are incorporated in qubits of a first quantum information processor, where the frequencies of the qubits are inversely proportional to the resistances of the Josephson junctions. A further example is illustrated in FIG. 11A which shows a further histogram of the resistances (in Ohms) of a second group of Josephson junctions. Similarly, to the first group of Josephson junctions, each of the second group of Josephson junctions are incorporated in qubits of a second quantum information processor (the frequencies of the qubits being inversely proportional to the resistances of the qubits).

In an example implementation of step 904 of the method of FIG. 9, a subset of the qubits may be identified which have a frequency which is above or below a mean frequency of all of the qubits. For example, with reference to FIG. 10A and FIG. 11A, all Josephson junctions having a resistance which is less than a mean resistance (all Josephson junctions falling within the dotted boxes shown in FIG. 10A and FIG. 11A) are identified as being Josephson junctions for resistance adjustment. This identification of Josephson junctions corresponds with equivalently identifying qubits for frequency adjustment, where each identified qubit has a frequency which is greater than a mean frequency.

At step 906 of the method of FIG. 9 a frequency of the at least one qubit identified for frequency adjustment is adjusted. For example, an electron beam annealing process as described herein (for example, according to the methods described above with reference to FIG. 5) may be applied to Josephson junctions included in the identified qubits so as to adjust the frequencies of the qubits. In at least some examples, the electron beam annealing process which is applied to the identified qubits may depend on the frequencies of the qubits. For example, different electron beam currents, different charge doses, different exposure patterns and/or different separations between an electron beam and a Josephson junction may be used to anneal different qubits of the identified qubits, so as to bring about different adjustments in frequency. However, in other examples, the same electron beam annealing process may be applied to each of the identified qubits.

Illustrative examples of results obtained by applying a frequency adjustment according to an example of step 906 of the method of FIG. 9 are shown in FIG. 10B, FIG. 10C, FIG. 10D, FIG. 11B, FIG. 11C and FIG. 11D. To obtain the results shown in FIG. 10B, FIG. 10C, FIG. 10D, FIG. 11B, FIG. 11C and FIG. 11D each of the Josephson junctions of the first and second groups of Josephson junctions (whose resistances are shown in FIG. 10A and FIG. 11A respectively) identified for resistance adjustment were subjected to substantially the same electron beam annealing process. That is, each of the Josephson junctions having a resistance less than a mean resistance of the respective group of Josephson junctions (those situated inside the dashed boxes shown in FIG. 10A and FIG. 11A) were subjected to substantially the same electron beam annealing process. In particular, each of the identified Josephson junctions were subjected to a 2 nA electron beam for a multiple shot exposure to deliver a total charge dose of 500 μC/cm².

FIG. 10B and FIG. 11B each illustrate two histograms of the resistances of the first and second groups of Josephson junctions before and after performing the electron beam annealing process described above. Results obtained with the first group of Josephson junctions are shown in FIG. 10B. Results obtained with the second group of Josephson junctions are shown in FIG. 11B. In each of FIG. 10B and FIG. 11B, the left-hand histogram represents the resistances of the respective group of Josephson junctions before the electron beam annealing process is applied. In each of FIG. 10B and FIG. 11B, the right-hand histogram represents the resistances of the respective group of Josephson junctions after the electron beam annealing process is applied. In the histograms shown in FIG. 10B and FIG. 11B the resistances are plotted as a normalised resistance (a ratio of each resistance with respect to the mean resistance).

FIG. 10C and FIG. 11C each illustrate histograms of the resistances of the first and second groups of Josephson junctions before and after performing the electron beam annealing process, where the before and after histograms are plotted on the same axes and plotted as resistance in Ohms. Results obtained with the first group of Josephson junctions are shown in FIG. 10C. Results obtained with the second group of Josephson junctions are shown in FIG. 11C.

FIG. 10D and FIG. 11D each illustrate scatter plots of the resistances of the first and second groups of Josephson junctions before and after performing the electron beam annealing process. The horizontal axes in FIG. 10D and FIG. 11D represents the resistances in Ohms of the Josephson junctions before the electron beam annealing process is applied. The vertical axes in FIG. 10D and FIG. 11D represents the resistances in Ohms of the Josephson junctions after the electron beam annealing process is applied. Results obtained with the first group of Josephson junctions are shown in FIG. 10D. Results obtained with the second group of Josephson junctions are shown in FIG. 11D.

With respect to the first group of Josephson junctions, whose results are shown in FIG. 10B, FIG. 10C and FIG. 10D the standard deviation of Josephson junction resistance was 2.57% of the mean resistance before the electron beam annealing process was applied (as shown in the left-hand histogram of FIG. 10B). After the electron beam annealing process was applied to the Josephson junctions identified for resistance adjustment, the standard deviation of Josephson junction resistance was reduced to 1.57%.

With respect to the second group of Josephson junctions, whose results are shown in FIG. 11B, FIG. 11C and FIG. 11D the standard deviation of Josephson junction resistance was 1.85% of the mean resistance before the electron beam annealing process was applied (as shown in the left-hand histogram of FIG. 11B). After the electron beam annealing process was applied to the Josephson junctions identified for resistance adjustment, the standard deviation of Josephson junction resistance was reduced to 1.07%.

As shown in each of FIG. 10D and FIG. 11D, the electron beam annealing process produced an approximately 100 Ohm increase in resistance to the identified Josephson junctions to which it was applied (for both the first and second groups of Josephson junctions).

The results presented in FIG. 10A, FIG. 10B, FIG. 10C, FIG. 10D, FIG. 11A, FIG. 11B, FIG. 11C and FIG. 11D have shown that an electron beam annealing process applied to an identified subset of Josephson junctions can be used to reduce a dispersion in resistance of the Josephson junctions. Equivalently, a dispersion in frequency of qubits in which the Josephson junctions are incorporated can also be reduced. Whilst not shown in the Figures, similar results have been obtained by performing electron beam annealing on Josephson junctions incorporated into qubits in a quantum information processor comprising a plurality of superconducting qubits. These results demonstrated that electron beam annealing was successfully used to adjust the resistance of Josephson junctions incorporated in superconducting qubits and in turn to adjust the frequency of the qubits. In particular, electron beam annealing processes were used to reduce a spread in frequencies of qubits incorporated into a single quantum information processor.

In the example electron beam annealing process described with reference to FIG. 10A, FIG. 10B, FIG. 10C, FIG. 10D, FIG. 11A, FIG. 11B, FIG. 11C and FIG. 11D, an electron beam annealing process for increasing the resistance of a Josephson junction was applied to each of the Josephson junctions which were identified for resistance adjustment. However, equivalent results could be achieved by applying an electron beam annealing process for decreasing the resistance of a Josephson junction to an identified subset of Josephson junctions. For example, Josephson junctions having a resistance above a mean resistance could be identified for resistance adjustment. An electron beam annealing process could then be applied to those identified Josephson junctions (those having a resistance greater than a mean resistance) to reduce the resistances of the identified Josephson junctions.

In the example electron beam annealing process described with reference to FIG. 10A, FIG. 10B, FIG. 10C, FIG. 10D, FIG. 11A, FIG. 11B, FIG. 11C and FIG. 11D, a substantially identical electron beam annealing process was applied to each of the Josephson junctions which were identified for resistance adjustment. However, in other examples, different electron beam annealing processes may be applied to different Josephson junctions. That is, an electron beam annealing process having one or more different parameters (e.g., a different electron beam current, a different charge dose, a different time period during which the electron beam is directed to heat the Josephson junction, a number of positions at which the electron beam is directed to heat the Josephson junction and/or a position at which the electron beam is directed to heat the Josephson junction (e.g., a proximity of the electron beam to the Josephson junction)) may be applied to different Josephson junctions. In at least some examples, parameters of an electron beam annealing process to be applied to a Josephson junction may be determined in dependence on a resistance of the Josephson junction (or equivalently on a frequency of a qubit in which the Josephson junction is incorporated). For example, Josephson junctions whose resistance lies further from the mean resistance may be subjected to an electron beam annealing process which brings about a larger change in resistance than an electron beam annealing process applied to Josephson junctions whose resistance lies closer to the mean resistance. It will be appreciated that such a process may bring about an even greater reduction in resistance and frequency dispersion than the process described above with reference to FIG. 10A, FIG. 10B, FIG. 10C, FIG. 10D, FIG. 11A, FIG. 11B, FIG. 11C and FIG. 11D.

Parameters of an electron beam annealing process to be applied to a given Josephson junction may be determined in dependence on an understanding of a relationship between electron beam annealing parameters and a change in resistance caused by an electron beam annealing process. Such a relationship may be captured, for example, in a calibration curve or lookup table representing a relationship between electron beam annealing parameters and a change in resistance caused by an electron beam annealing process.

In the example electron beam annealing process described with reference to FIG. 10A, FIG. 10B, FIG. 10C, FIG. 10D, FIG. 11A, FIG. 11B, FIG. 11C and FIG. 11D all of the Josephson junctions identified for resistance adjustment were subjected to an electron beam annealing process to increase the resistances of the identified Josephson junctions. In other examples, all of the Josephson junctions identified for resistance adjustment may be subjected to an electron beam annealing process to decrease the resistances of the identified Josephson junctions.

In still further examples, a first subset of the identified Josephson junctions may be subjected to an electron beam annealing process to decrease the resistance of the first subset of identified Josephson junctions. A second subset of the identified Josephson junctions may be subjected to an electron beam annealing process to decrease the resistance of the second subset of identified Josephson junctions. That is, the resistance of at least one of the identified Josephson junctions may be increased and at least one of the identified Josephson junctions may be decreased.

In at least some examples, Josephson junctions whose resistance is less than a mean resistance may be subjected to an electron beam annealing process to increase the resistances of the Josephson junctions. Josephson junctions whose resistance is greater than a mean resistance may be subjected to an electron beam annealing process to decrease the resistances of the Josephson junctions. Such a process may be used to generally move the resistances of at least some of the Josephson junctions closer to the mean resistance and may bring about an even greater reduction in resistance and frequency dispersion than the process described above with reference to FIG. 10A, FIG. 10B, FIG. 10C, FIG. 10D, FIG. 11A, FIG. 11B, FIG. 11C and FIG. 11D.

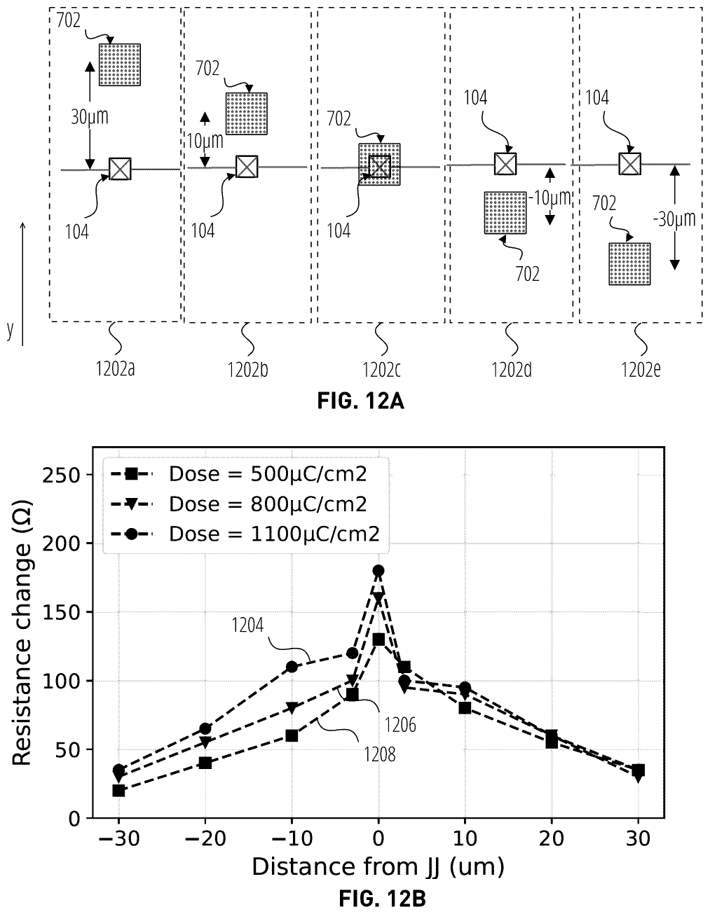

As was explained above with reference to FIG. 6 and FIG. 7, an adjustment of resistance of a Josephson junction 104 (and correspondingly a change in frequency of a qubit in which the Josephson junction 104 is incorporated) can be controlled by controlling the position(s) at which an electron beam is directed to be incident, relative to the Josephson junction. Results are presented in FIG. 12A, FIG. 12B, FIG. 13A and FIG. 13B which demonstrate that different positions of an electron beam 110 can be used to bring about different changes in resistance of a Josephson junction 104.

FIG. 12A is a schematic illustration of an exposure pattern 702 located at a plurality of different positions relative to a Josephson junction 104. The exposure pattern 702 used in the example of FIG. 12A is similar to the exposure pattern 702 described above with reference to FIG. 7. In particular, the exposure pattern 702 comprises a plurality of exposure spots (arranged in a grid) at which an electron beam is directed to be incident.

In the exposure example labelled 1202a in FIG. 12A the exposure pattern 702 is directed such that it is separated from the Josephson junction 104 by a distance of approximately 30 μm in the positive y-direction. In the exposure example labelled 1202b in FIG. 12A the exposure pattern 702 is directed such that it is separated from the Josephson junction 104 by a distance of approximately 10 μm in the positive y-direction. In the exposure example labelled 1202c in FIG. 12A the exposure pattern 702 is directed such that it is centered on the Josephson junction 104. In the exposure example labelled 1202d in FIG. 12A the exposure pattern is separated from the Josephson junction 104 by a distance of approximately 10 μm in the negative y-direction. In the exposure example labelled 1202e in FIG. 12A the exposure pattern 702 is separated from the Josephson junction 104 by a distance of approximately 30 μm in the negative y-direction.

FIG. 12B is a graph of changes in resistance to Josephson junctions 104 which result from directing exposure patterns 702 to be incident at different separations from the Josephson junctions 104, as described above with reference to FIG. 12A. The results plotted in the graph of FIG. 12B were obtained through experimentation using an electron beam having a current of 100 nA. A change in resistance (in Ohms (2) which results from each electron beam annealing process is plotted on the y-axis. A separation between an exposure pattern 702 and a Josephson junction 104 which was used in each electron beam annealing process is plotted on the x-axis. Results are shown for separations of 30 μm (corresponding to the exposure example 1202a), 20 μm, 10 μm (corresponding to the exposure example 1202b), 3 μm, Oum (corresponding to the exposure example 1202c), −3 μm, −10 μm (corresponding to the exposure example 1202d), −20 μm and −30 μm (corresponding to the exposure example 1202e). For each separation, results were obtained using different charge doses delivered to each exposure spot in the respective exposure pattern 702. In particular, results were obtained using charge doses of 500 μC/cm² (illustrated by the line labelled 1208 in FIG. 12B), 800 μC/cm² (illustrated by the line labelled 1206 in FIG. 12B) and 1100 μC/cm² (illustrated by the line labelled 1204 in FIG. 12B).

As can be seen from the results presented in FIG. 12B, the resistance change induced by an electron beam annealing process depends at least in part on a distance between the exposure pattern 702 and the Josephson junction 104. For the currents and charge doses used to generate the results shown in FIG. 12B, the change in resistance is generally greater for smaller distances between the Josephson junction 104 and the exposure pattern 702. For the currents and charge doses used to generate the results shown in FIG. 12B all of the electron beam annealing processes resulted in an increase in the resistance of a Josephson junction 104. However, as was described above, it has been found that by varying the parameters (e.g., current, charge dose etc.) used in an electron beam annealing process, for at least some parameter values a decrease in resistance of a Josephson junction 104 may be induced.

The results shown in FIG. 12B further demonstrate that the resistance change induced in the Josephson junction 104 is further dependent on the charge dose delivered during an electron beam annealing process.

As is demonstrated by the results shown in FIG. 12B, the change in resistance which is induced in a Josephson junction 104 has been found to depend both on a distance between an exposure pattern 702 and the Josephson junction 104 and on the charge dose delivered during an electron beam annealing process. In at least some examples, one or more of a distance between an exposure pattern 702 (which may comprise a single exposure spot 604 or may comprise a plurality of exposure spots 604) and a Josephson junction 104, and a charge dose may be controlled in order to control a resistance change which is induced in the Josephson junction 104. As was explained above, controlling a resistance change of a Josephson junction 104 can be used to control a change in frequency of a qubit in which the Josephson junction 104 is incorporated.

FIG. 13A is a schematic illustration of different exposure patterns 1302, 1304, 1306 which were used to generate results which are shown in FIG. 13B. As shown in FIG. 13A, electron beam annealing processes were applied to Josephson junctions 104 using a plurality of different exposure patterns 1302, 1304, 1306 each comprising a plurality of exposure spots 604 at which an electron beam was directed to be incident. The exposure patterns include a fully closed exposure pattern 1302 (corresponding to the exposure pattern 602a described above with reference to FIG. 6), a thick loop exposure pattern 1304 (corresponding to the exposure pattern 602b described above with reference to FIG. 6) and a thin loop exposure pattern 1306 (corresponding to the exposure pattern 602c described above with reference to FIG. 6). Finally, for way of comparison, results were obtained for a control 1308 on which no electron beam annealing process was used.

FIG. 13B is a graph of changes in resistance to Josephson junctions 104 which resulted from subjecting Josephson junctions 104 to different electron beam annealing processes using different exposure patterns as described above with reference to FIG. 13A. The results plotted in the graph of FIG. 13B were obtained through experimentation using an electron beam having a current of 100 nA. A change in resistance (in Ohms 2) which results from each electron beam annealing process is plotted on the y-axis. A charge dose (in μC/cm²) which was used in each electron beam annealing process is plotted on the x-axis. Results are shown for a thick loop exposure pattern 1304, a thin loop exposure pattern 1306 and a control 1308. For each exposure pattern, results were obtained using different charge doses delivered to each exposure spot in the respective exposure pattern. In particular, results were obtained using charge doses of 500 μC/cm², 800 μC/cm² and 1100 μC/cm².

As can be seen by the results shown in FIG. 13B, the change in resistance which is induced in a Josephson junction 104 depends both on the charge dose which is used and on the exposure pattern which is used. For the parameter values used to generate the results shown in FIG. 13B, it was found that increasing the charge dose generally increases the change in resistance which is induced. It was further found that the largest changes in resistance resulted from using a fully closed exposure pattern 1302, followed by a thick loop exposure pattern 1304 and with a thin loop exposure pattern 1306 inducing the smallest changes in resistance.

All of the results shown in FIG. 13B demonstrate an increase in the resistance of a Josephson junction 104. However, as was described above, it has been found that for other parameter values (e.g., current, charge dose etc.) used in an electron beam annealing process, a decrease in resistance of a Josephson junction 104 may be induced.

As is demonstrated by the results shown in FIG. 13B, the change in resistance which is induced in a Josephson junction 104 has been found to depend both on an exposure pattern which is used and on the charge dose delivered during an electron beam annealing process. In at least some examples, one or more of an exposure pattern and a charge dose may be controlled in order to control a resistance change which is induced in the Josephson junction 104. As was explained above, controlling a resistance change of a Josephson junction 104 can be used to control a change in frequency of a qubit in which the Josephson junction 104 is incorporated.

Several examples have been described above in the context of adjusting the resistance of Josephson junctions, and equivalently the frequency of qubits, in order to reduce a dispersion in qubit frequency in a quantum information processor. However, the methods described herein may be used to make any form of adjustment to the frequency of a qubit. For example, for a given quantum information processor comprising a plurality of qubits, there may be a given target or design set of qubit frequencies which it is desirable to achieve. The target set of frequencies may comprise each of the plurality of qubits having substantially the same frequency. Alternatively, the target set of frequencies may comprise at least some of the plurality of qubits having different frequencies. For example, qubit frequencies may be designed such that different qubits have different frequencies so as to reduce unwanted crosstalk between different qubits. Irrespective of the target frequencies for a given quantum information processor, variance in the fabrication of Josephson junctions may results in differences between the qubit frequencies in a quantum information processor and the target frequencies. The methods described herein may be used to adjust the frequency of at least one qubit in order to reduce any difference between qubit frequencies and the target frequencies.

Examples of qubits have been described and depicted herein in which each qubit includes a Josephson junction. In some examples, one or more qubits may comprise a plurality of Josephson junctions. For example, a qubit may comprise two Josephson junctions. Any of the methods described herein for adjusting a frequency of a qubit may be applied to a qubit comprising a plurality of Josephson junctions. Such methods may be applied, for example, by applying an electron beam annealing process to a Josephson junction of the plurality of Josephson junctions. In some examples, an electron beam annealing process may be applied to a plurality of Josephson junctions included in a single qubit. For example, the frequency of a qubit comprising a plurality of Josephson junctions may be adjusted by applying an electron beam annealing process to two or more of the plurality of Josephson junctions. The two or more of the plurality of Josephson junctions may comprise a subset of the plurality of Josephson junctions (e.g., less than all of the plurality of Josephson junctions) or may comprise all of the plurality of Josephson junctions.

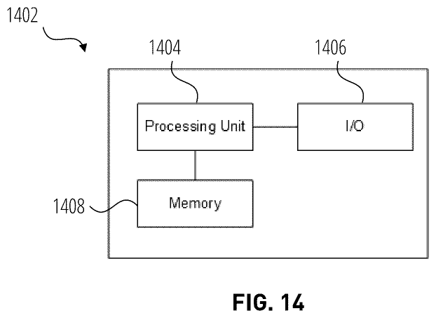

Various methods have been described herein in which some of the method steps may be implemented on any suitable electronic device (such as a computing device) and/or combination of electronic devices (e.g. computing devices). For example, methods steps such as step 904 of the method of FIG. 9 may be carried out by an electronic device such as a computing device. FIG. 14 is a schematic illustration of an example electronic device 1402 which may be used to implement all or part of any method described herein.

The electronic device 1402 may include at least one processing unit 1404, memory 1408 and an input/output interface 1406. The processing unit 1404 may include any suitable processor and/or combination of processors. For example, the processing unit 1404 may include one or more of a Central Processing Unit (CPU) and a Graphical Processing Unit (GPU). The memory 1408 may include volatile memory and/or non-volatile/persistent memory. The memory 1408 may, for example, be used to store data such as an operating system, instructions to be executed by the processing unit (e.g. in the form of software to be executed by the processing unit), configuration information related to the electronic device 1402, session information and/or configuration or registration information associated with any other device, node or module in the network. In some examples, the memory 1408 may be used to store instructions for executing any of the methods disclosed herein.

At least the processing unit 1404 is connected to the input/output interface 1406. The input/output interface 1406 may facilitate communication with one or more other devices. For example, the input/output interface 1406 may be operable to transmit and/or receive communications to/from other devices in a network.

Optionally, the electronic device 1402 may further include a display (not shown). The display may comprise any suitable electronic display such as a touch sensitive display. The display may be connected to at least to the processing unit 1404. The processing unit 1404 may generate display signals which are sent to the display in order to cause the display information.

In the interest of conciseness not all possible alternatives which fall within the scope of the present disclosure have been explicitly discussed herein. As the skilled person will appreciate, in the present disclosure any aspect discussed from the perspective of an element being operable to do an action also discloses the same feature from the perspective of a method including a method step corresponding to the action. Similarly, any discussion presented from the perspective of a method step also discloses the same features from the perspective of any one or more suitable elements being operable or configured to carry out some or all of the method step. It is also considered within the present disclosure that for any method step(s), there can be a computer program configured to carry out, when executed, the method step(s).

Examples of the present disclosure can be realised in the form of hardware, software or a combination of hardware and software. Any such software may be stored in the form of volatile or non-volatile storage such as, for example, a storage device like a ROM, whether erasable or rewritable or not, or in the form of memory such as, for example, RAM, memory chips, device or integrated circuits or on an optically or magnetically readable medium such as, for example, a CD, DVD, magnetic disk or magnetic tape. It will be appreciated that the storage devices and storage media are embodiments of machine-readable storage that are suitable for storing a program or programs that, when executed, implement examples of the present disclosure. Accordingly, examples provide a program comprising code for implementing a system or method as claimed in any preceding claim and a machine readable storage storing such a program. Still further, examples of the present disclosure may be conveyed electronically via any medium such as a communication signal carried over a wired or wireless connection and examples suitably encompass the same.

Features, integers, characteristics, or groups described in conjunction with a particular aspect, embodiment or example of the invention or disclosure are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing examples.

1. A method of adjusting the frequency of a qubit comprising a Josephson junction, the method comprising:
directing an electron beam to heat the Josephson junction; and
cooling the Josephson junction following the heating of the Josephson junction by the electron beam,
wherein the heating and cooling of the Josephson junction serves to alter a resistance of the Josephson junction, and wherein the alteration of the resistance of the Josephson junction changes the frequency of the qubit.

2. The method of claim 1, wherein directing the electron beam to heat the Josephson junction comprises directing the electron beam to be incident on the Josephson junction.

3. The method of claim 1, wherein directing the electron beam to heat the Josephson junction comprises directing the electron to beam incident on a component which is thermally coupled to the Josephson junction, thereby causing heating of the component and heating of the Josephson junction through heat conduction from the heated component.

4. The method of claim 3, wherein the component comprises a portion of a substrate supporting the Josephson junction.

5. The method of claim 1, wherein the qubit comprises the Josephson junction connected between two superconducting electrodes.

6. The method of claim 5, wherein the superconducting electrodes are arranged to be coaxial with each other.

7. The method of claim 1, wherein the directing an electron beam to heat the Josephson junction comprises directing the electron beam with a first current below a threshold current so as to increase the resistance of the Josephson junction and decrease the frequency of the qubit.

8. The method of claim 1, wherein the directing an electron beam to heat the Josephson junction comprises directing the electron beam with a first current greater than a threshold current so as to decrease the resistance of the Josephson junction and increase the frequency of the qubit.

9. The method of claim 1, wherein the directing an electron beam to heat the Josephson junction comprises directing the electron beam to heat the Josephson junction for a single continuous exposure time period.

10. The method of claim 1, wherein the directing an electron beam to heat the Josephson junction comprises directing a plurality of pulses of an electron beam to heat the Josephson junction.

11. The method of claim 10, wherein at least some of the plurality of pulses of an electron beam are directed to be incident at a plurality of different positions.

12. The method of claim 11, wherein the plurality of different positions are arranged to form an exposure pattern which encloses the Josephson junction.

13. The method of claim 1, wherein the directing an electron beam to heat the Josephson junction comprises directing an electron beam having a beam diameter of less than 200 nm to be heat the Josephson junction.

14. The method of claim 1, wherein the directing an electron beam to heat the Josephson junction comprises directing an electron beam having a current of greater than 0.1 nA to heat the Josephson junction.

15. The method of claim 1, wherein the directing an electron beam to heat the Josephson junction comprises using an electron beam lithography apparatus to direct the electron beam to heat the Josephson junction.

16. A method of adjusting qubit frequencies of a quantum information processor comprising a plurality of qubits, wherein each qubit comprises a Josephson junction, the method comprising:
determining a frequency of each of the plurality of qubits;
identifying, based on the determined frequencies of the plurality of qubits, at least one of the qubits for frequency adjustment; and
adjusting a frequency of the at least one qubit identified for frequency adjustment, according to the method of claim 1.

17. A method according to claim 16, wherein determining a frequency of each of the plurality of qubits comprises measuring a resistance of a Josephson junctions included in each of the plurality of qubits.

18. A method according to claim 16, wherein identifying at least one of the plurality of qubits for frequency adjustment comprises identifying at least one of the plurality of qubits having a frequency which can be adjusted to reduce a dispersion of the frequencies of the plurality of qubits.

19. A method according to claim 16 wherein adjusting the frequency of the at least one qubit identified for frequency adjustment comprises adjusting the frequency of the at least one identified qubit so as to reduce a dispersion of the frequencies of the plurality of qubits.

20. A method according to claim 16 wherein adjusting the frequency of the at least one qubit identified for frequency adjustment comprises increasing the resistance of a Josephson junction of at least a first of the at least one qubit identified for frequency adjustment so as to decrease the frequency of the at least a first of the at least one qubit identified for frequency adjustment.

21. A method according to claim 16, wherein adjusting the frequency of the at least one qubit identified for frequency adjustment comprises decreasing the resistance of a Josephson junction of at least a second of the at least one qubit identified for frequency adjustment so as to increase the frequency of the at least a second of the at least one qubit identified for frequency adjustment.

22. A method according to claim 16, wherein adjusting a frequency of the at least one qubit identified for frequency adjustment, according to the method of any one of claims 1-13 further comprises:
determining a property of the electron beam to be directed to heat a Josephson junction in dependence on a determined frequency of a qubit in which the Josephson junction is included; and
directing the electron beam to heat the Josephson junction with the determined property of the electron beam.

23. A quantum information processor comprising at least one qubit comprising a Josephson junction, wherein the frequency of the at least one qubit has been adjusted using a method according to claim 1.

24. A quantum information processor comprising a plurality of qubits each comprising a Josephson junction, wherein the frequency of at least one of the plurality of qubits has been adjusted using a method according to claim 16.
